(19) United States
(12) Patent Application Publication
(10) Pub. No.: US 2026/0129754 A1
(43) Pub. Date: May 7, 2026

(54) CIRCUIT BOARD AND METHOD OF MANUFACTURING CIRCUIT BOARD

(71) Applicants: SUMITOMO ELECTRIC INDUSTRIES, LTD., Osaka (JP); SUMITOMO ELECTRIC PRINTED CIRCUITS, INC., Shiga (JP)

(72) Inventors: Shingo KAIMORI, Osaka (JP); Satoshi KIYA, Shiga (JP); Hiroshi UEDA, Shiga (JP); Motohiko SUGIURA, Osaka (JP); Eiko IMAZAKI, Osaka (JP)

(73) Assignees: SUMITOMO ELECTRIC INDUSTRIES, LTD., Osaka (JP); SUMITOMO ELECTRIC PRINTED CIRCUITS, INC., Shiga (JP)

(21) Appl. No.: 19/118,197

(22) PCT Filed: Sep. 4, 2023
(86) PCT No.: PCT/JP2023/032203

§ 371 Date: Apr. 3, 2025

(30) Foreign Application Priority Data
Oct. 7, 2022 (JP) 2022-162209

(51) Int. Cl. H05K 1/11; H05K 3/00; H05K 3/40

(52) U.S. Cl. CPC H05K 1/115; H05K 3/0058; H05K 3/4038; H05K 2201/0158; H05K 2201/0209; H05K 2203/061; H05K 2203/107

(57) ABSTRACT

A circuit board includes a fluororesin layer, an adherend layer and an adhesion layer bonding the fluororesin layer and the adherend layer together, the fluororesin layer contains polytetrafluoroethylene and a first inorganic filler, a content of the first inorganic filler in the fluororesin layer is 50% by volume to 66% by volume, the adhesion layer contains a resin and a second inorganic filler, a content of a fluororesin in the resin is 5% by mass or less, a content of the second inorganic filler in the adhesion layer is 29% by volume to 47% by volume, and a through-hole extending through the fluororesin layer and the adhesion layer is formed.

### TECHNICAL FIELD

The present disclosure relates to a circuit board and a method of manufacturing a circuit board.

The present application claims priority based on Japanese Patent Application No. 2022-162209 filed on Oct. 7, 2022, and the entire contents of the Japanese patent application are incorporated herein by reference.

### BACKGROUND ART

In order to improve high-frequency characteristics of printed circuit boards, studies have been conducted on the use of a fluororesin layer containing a fluororesin, such as polytetrafluoroethylene, and an inorganic filler, such as silica, as a dielectric layer (PTL 1).

To stack a board (circuit board) on which circuits have been formed by processing a metal layer of a substrate, and another substrate or another circuit board, a bonding sheet is used. For example, a circuit board, a bonding sheet, and another substrate are stacked in this order and then heated until the bonding sheet is softened. In the state where the bonding sheet is softened, the bonding sheet is deformed by applying a pressure. The circuit board and the other substrate are bonded together while gaps between circuits are filled with the bonding sheet (PTL 2).

### CITATION LIST

### Patent Literature

PTL 1: International Publication No. 2021/235276
PTL 2: Japanese Unexamined Patent Application Publication No. 2016-27131

### SUMMARY OF INVENTION

A circuit board according to the present disclosure includes:
a fluororesin layer;
an adherend layer; and
an adhesion layer bonding the fluororesin layer and the adherend layer together,
wherein the fluororesin layer contains polytetrafluoroethylene and a first inorganic filler,
a content of the first inorganic filler in the fluororesin layer is 50% by volume to 66% by volume.
the adhesion layer contains a resin and a second inorganic filler,
a content of a fluororesin in the resin is 5% by mass or less,
a content of the second inorganic filler in the adhesion layer is 29% by volume to 47% by volume, and
a through-hole extending through the fluororesin layer and the adhesion layer is formed.

A method of manufacturing a circuit board according to the present disclosure is a method of manufacturing the above circuit board, the method including:
holding a laminate in which the fluororesin layer, the adhesion layer, and the adherend layer are stacked in this order at a temperature of 180° C. or lower to soften the adhesion layer, thereby bonding the fluororesin layer and the adherend layer together.

A method of manufacturing a circuit board according to the present disclosure includes:
preparing a fluororesin laminate including a fluororesin layer having a first main surface and a second main surface opposite to the first main surface, and a second metal layer composed of a metal and disposed on the second main surface;
preparing a first resin laminate including a first resin layer having a third main surface and a fourth main surface opposite to the third main surface, and a first metal layer disposed on the third main surface;
preparing an adhesion layer;
forming a first laminate by stacking the fluororesin laminate, the adhesion layer, and the first resin laminate in this order such that the first main surface is in contact with the adhesion layer and holding the adhesion layer at a temperature of 180° C. or lower to soften the adhesion layer, thereby bonding the fluororesin laminate and the first resin laminate together;
removing at least a part of the fluororesin layer and at least a part of the adhesion layer to form a through-hole extending through the fluororesin layer and the adhesion layer; and
forming a connecting portion on an inner wall surface of the fluororesin layer defining a part of the through-hole and an inner wall surface of the adhesion layer defining a part of the through-hole,
wherein the fluororesin layer contains polytetrafluoroethylene and a first inorganic filler,
a content of the first inorganic filler in the fluororesin layer is 50% by volume to 66% by volume,
the adhesion layer contains a resin and a second inorganic filler,
a content of a fluororesin in the resin is 5% by mass or less, and
a content of the second inorganic filler in the adhesion layer is 29% by volume to 47% by volume.

### BRIEF DESCRIPTION OF DRAWINGS

FIG. 1 is a schematic cross-sectional view of a circuit board according to Embodiment 1.

FIG. 2A is a view illustrating a method of manufacturing a circuit board according to Embodiment 2.

FIG. 2B is a view illustrating the method of manufacturing a circuit board according to Embodiment 2.

FIG. 2C is a view illustrating the method of manufacturing a circuit board according to Embodiment 2.

FIG. 3 is a schematic cross-sectional view of a circuit board according to Embodiment 3.

FIG. 4A is a view illustrating a method of manufacturing a circuit board according to Embodiment 3.

FIG. 4B is a view illustrating the method of manufacturing a circuit board according to Embodiment 3.

FIG. 4C is a view illustrating the method of manufacturing a circuit board according to Embodiment 3.

FIG. 5 is a schematic cross-sectional view of a circuit board according to Embodiment 4.

FIG. 6 is a schematic cross-sectional view of a circuit board according to Embodiment 5.

FIG. 7A is a view illustrating a method of manufacturing a circuit board according to Embodiment 5.

FIG. 7B is a view illustrating the method of manufacturing a circuit board according to Embodiment 5.

FIG. 8 is a view illustrating a scooped part.

FIG. 9 is a view for explaining a method for measuring the length of a scooped part.

### DETAILED DESCRIPTION

### Problems to be Solved by Present Disclosure

In recent years, the amount of information communication has been increasing. For example, in devices such as IC cards and mobile phone terminals, communication in high-frequency bands such as microwaves and millimeter waves has become popular. Therefore, there has been a demand for a printed circuit board having excellent high-frequency characteristics, for example, a printed circuit board with a low transmission loss in a high-frequency band. In general, a laminate obtained by stacking a metal layer (for example, copper foil) on a dielectric layer is used as a substrate for manufacturing such a high-frequency printed circuit board.

A bonding sheet having a low softening temperature can be bonded with a general-purpose press machine and is excellent in terms of productivity. However, the present inventors have found a disadvantage in that, in a laminate produced by using a bonding sheet having a low softening temperature, a scooped part is likely to be generated when a through-hole for a via-hole is formed by laser processing.

The scooped part will be described with reference to FIG. 8. A circuit board 1 includes an adhesion layer 12 (corresponding to a bonding sheet) containing polypropylene as a main component. When a through-hole extending through a fluororesin layer 10 and the adhesion layer 12 is formed from the fluororesin layer 10 to a first metal layer 13 by laser processing, a scooped part 25 is generated near the interface between the fluororesin layer 10 and the adhesion layer 12. Inner wall surfaces of the fluororesin layer 10 and the adhesion layer 12 are subjected to a plating treatment to form a via-hole. However, the portion of the scooped part 25 is less likely to be plated. Thus, a portion where plating is not sufficiently performed is generated in the via-hole, and reliability of the circuit board is likely to decrease.

An object of the present disclosure is to provide a circuit board in which a fluororesin layer and an adherend layer are bonded together by pressing at a low temperature. In addition, an object of the present disclosure is to provide a circuit board in which, in a case where a through-hole extending through a fluororesin layer and an adhesion layer is formed, the generation of a scooped part near the interface between the fluororesin layer and the adhesion layer is suppressed.

### Advantageous Effects of Present Disclosure

The present disclosure can provide a circuit board in which a fluororesin layer and an adherend layer are bonded together by pressing at a low temperature. In addition, the present disclosure can provide a circuit board in which, in a case where a through-hole extending through a fluororesin layer and an adhesion layer is formed, the generation of a scooped part near the interface between the fluororesin layer and the adhesion layer is suppressed.

### DESCRIPTION OF EMBODIMENTS OF PRESENT DISCLOSURE

First, embodiment of the present disclosure will be listed and described.

(1) A circuit board according to the present disclosure includes:
a fluororesin layer;
an adherend layer; and
an adhesion layer bonding the fluororesin layer and the adherend layer together,
wherein the fluororesin layer contains polytetrafluoroethylene and a first inorganic filler,
a content of the first inorganic filler in the fluororesin layer is 50% by volume to 66% by volume,
the adhesion layer contains a resin and a second inorganic filler,
a content of a fluororesin in the resin is 5% by mass or less,
a content of the second inorganic filler in the adhesion layer is 29% by volume to 47% by volume, and
a through-hole extending through the fluororesin layer and the adhesion layer is formed.

The present disclosure can provide a circuit board in which a fluororesin layer and an adherend layer are bonded together by pressing at a low temperature. In addition, the present disclosure can provide a circuit board in which, even in the case where a through-hole extending through a fluororesin layer and an adhesion layer is formed, the generation of a scooped part near the interface between the fluororesin layer and the adhesion layer is suppressed. In the present disclosure, the “low temperature” means a temperature of 180° C. or lower.

(2) In (1) above, the first inorganic filler may contain silica. This can decrease a thermal expansion coefficient of the fluororesin layer. Herein, the thermal expansion coefficient of the fluororesin layer is a linear expansion coefficient in the thickness direction of the fluororesin layer (thermal expansion coefficient with respect to the length along an axis perpendicular to the layer surface of the fluororesin layer).

(3) In (1) or (2) above, the second inorganic filler may contain silica. This can further suppress the generation of a scooped part.

(4) In any one of (1) to (3) above, the second inorganic filler may contain boron nitride. This can further suppress the generation of a scooped part.

(5) In any one of (1) to (4) above, at least one of an inner wall surface of the fluororesin layer defining a part of the through-hole and an inner wall surface of the adhesion layer defining a part of the through-hole may have a scooped part, and the scooped part may have a length of less than 25 μm. This improves reliability of the circuit board.

(6) In any one of (1) to (5) above, the adhesion layer may have a ratio A/B of an elastic modulus A at 160° C. to an elastic modulus B at 20° C. of 0.08 or less. This improves adhesiveness between the fluororesin layer and a metal layer at a low temperature.

(7) In any one of (1) to (6) above, the resin may contain a polyolefin or a polystyrene-based elastomer. This improves adhesiveness between the fluororesin layer and a metal layer at a low temperature.

(8) In any one of (1) to (7) above, the adherend layer may include a first metal layer and a first resin layer, and the first metal layer may be disposed on a surface of the first resin layer facing the fluororesin layer.

This enables formation of a circuit on the first metal layer.

(9) In any one of (1) to (7) above, the adherend layer may include a first metal layer and a first resin layer, and the first resin layer may be disposed on a surface of the first metal layer facing the fluororesin layer. This enables formation of a circuit on the first metal layer.

(10) in (8) or (9) above, the fluororesin layer may have a first main surface facing the adhesion layer and a second main surface opposite to the first main surface, and the circuit board may further include a second metal layer disposed on the second main surface.

This enables formation of a circuit on the second metal layer.

(11) In (10) above, the circuit board may further include a connecting portion electrically connecting the first metal layer and the second metal layer to each other, wherein the connecting portion may be formed in the through-hole.

This enables the first metal layer and the second metal layer to be electrically connected to each other.

(12) In (10) or (11) above, when viewed from a direction perpendicular to the second main surface, the first metal layer may be formed in a region overlapping the through-hole. This enables the shape of the connecting portion to be defined with high accuracy.

(13) In (10) or (11) above, when viewed from a direction perpendicular to the first main surface, the second metal layer may be formed in a region overlapping the through-hole. This enables the shape of the connecting portion to be defined with high accuracy.

(14) A method of manufacturing a circuit board according to the present disclosure is a method of manufacturing the circuit board described in any one of (1) to (13) above, the method including:
holding a laminate in which the fluororesin layer, the adhesion layer, and the adherend layer are stacked in this order at a temperature of 180° C. or lower to soften the adhesion layer, thereby bonding the fluororesin layer and the adherend layer together.

The present disclosure can provide a circuit board in which a fluororesin layer and an adherend layer are bonded together by pressing at a low temperature. In addition, the present disclosure can provide a circuit board in which, even in the case where a through-hole extending through a fluororesin layer and an adhesion layer is formed, the generation of a scooped part near the interface between the fluororesin layer and the adhesion layer is suppressed.

(15) A method of manufacturing a circuit board according to the present disclosure includes:
preparing a fluororesin laminate including a fluororesin layer having a first main surface and a second main surface opposite to the first main surface, and a second metal layer disposed on the second main surface;
preparing a first resin laminate including a first resin layer having a third main surface and a fourth main surface opposite to the third main surface, and a first metal layer disposed on the third main surface;
preparing an adhesion layer;
forming a first laminate by stacking the fluororesin laminate, the adhesion layer, and the first resin laminate in this order such that the first main surface is in contact with the adhesion layer and holding the adhesion layer at a temperature of 180° C. or lower to soften the adhesion layer, thereby bonding the fluororesin laminate and the first resin laminate together;
removing at least a part of the fluororesin layer and at least a part of the adhesion layer to form a through-hole extending through the fluororesin layer and the adhesion layer; and
forming a connecting portion on an inner wall surface of the fluororesin layer defining a part of the through-hole and an inner wall surface of the adhesion layer defining a part of the through-hole,
wherein the fluororesin layer contains polytetrafluoroethylene and a first inorganic filler,
a content of the first inorganic filler in the fluororesin layer is 50% by volume to 66% by volume,
the adhesion layer contains a resin and a second inorganic filler,
a content of a fluororesin in the resin is 5% by mass or less, and
a content of the second inorganic filler in the adhesion layer is 29% by volume to 47% by volume.

The present disclosure can provide a circuit board in which a fluororesin layer and an adherend layer are bonded together by pressing at a low temperature. In addition, the present disclosure can provide a circuit board in which, even in the case where a through-hole extending through a fluororesin layer and an adhesion layer is formed, the generation of a scooped part near the interface between the fluororesin layer and the adhesion layer is suppressed.

(16) In (15) above, the preparing the first resin laminate may further include forming a first circuit on the first resin laminate by etching at least a part of the first metal layer. This enables the first circuit to be embedded in the adhesion layer.

(17) In (15) or (16) above, the preparing the fluororesin laminate may further include forming a second circuit on the fluororesin laminate by etching at least a part of the second metal layer. This enables the wiring density of the circuit board to be increased by formation of the second circuit.

(18) in (15) or (16) above, the forming the first laminate may further include forming a second circuit on the fluororesin laminate by etching at least a part of the second metal layer. This enables the wiring density of the circuit board to be increased by formation of the second circuit.

(19) In any one of (15) to (18) above, the through-hole may be formed by laser processing. This enables the through-hole to be formed with high accuracy.

(20) In any one of (15) to (19) above, at least one of the inner wall surface of the fluororesin layer and the inner wall surface of the adhesion layer may have a scooped part, and
the scooped part may have a length of less than 25 μm. This improves reliability of the circuit board.

### DETAILS OF EMBODIMENTS OF PRESENT DISCLOSURE

Circuit boards and methods of manufacturing the circuit boards according to the present disclosure will be described below with reference to the drawings. In the drawings of the present disclosure, the same reference numeral represents the same portion or a corresponding portion. The relationships of the dimensions such as length, width, thickness, and depth are appropriately changed for the sake of clarity and simplification of the drawings and do not necessarily represent the actual dimensional relationships.

In the present disclosure, the notation “from A to B” (where A and B are numerical values) means the range from the upper limit to the lower limit (A or more and B or less). When the unit is not described in A but is described only in B, the unit of A and the unit of B are the same.

In the present disclosure, when a compound is represented by a chemical formula and the atomic ratio is not limited, the compound includes compounds with all known atomic ratios and is not limited to only compounds in the stoichiometric range.

In the present disclosure, when one or more numerical values are described as each of the lower limit and the upper limit of a numerical range, it is assumed that a combination of any one numerical value described as the lower limit and any one numerical value described as the upper limit is disclosed. For example, when a1, b1, and c1 are described as lower limits and a2, b2, and c2 are described as upper limits, it is assumed that a1 to a2, a1 to b2, a1 to c2, b1 to a2, b1 to b2, b1 to c2, c1 to a2, c1 to b2, and c1 to c2 are disclosed.

### Embodiment 1: Circuit Board (1)

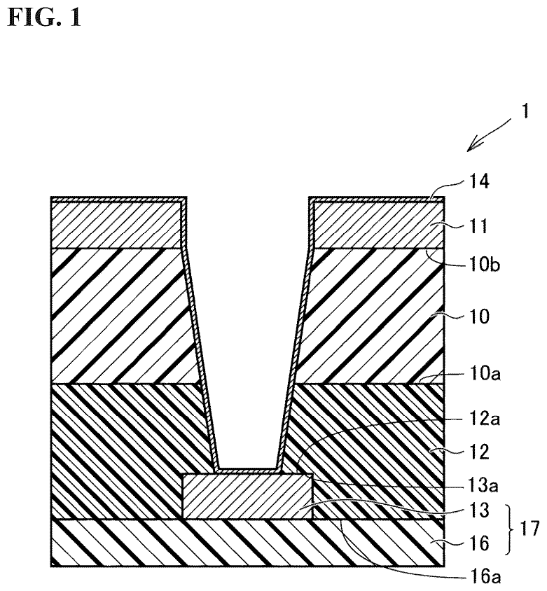

A circuit board according to an embodiment (hereinafter, also referred to as “Embodiment 1”) of the present disclosure and a method of manufacturing the circuit board will be described with reference to FIG. 1. A circuit board 1 of Embodiment 1 includes a fluororesin layer 10, an adherend layer 17, and an adhesion layer 12 bonding the fluororesin layer 10 and the adherend layer 17 together. The fluororesin layer 10 contains polytetrafluoroethylene and a first inorganic filler. A content of the first inorganic filler in the fluororesin layer 10 is 50% by volume to 66% by volume. The adhesion layer 12 contains a resin and a second inorganic filler. A content of a fluororesin in the resin is 5% by mass or less. A content of the second inorganic filler in the adhesion layer 12 is 29% by volume to 47% by volume. A through-hole extending through the fluororesin layer 10 and the adhesion layer 12 is formed in the circuit board 1.

The circuit board 1 of Embodiment 1 is a circuit board in which the fluororesin layer 10 and the adherend layer 17 are bonded together with the adhesion layer 12 by pressing at a low temperature. In the circuit board 1, even in the case where the through-hole extending through and the fluororesin layer 10 and the adhesion layer 12 is formed, the generation of a scooped part near the interface between the fluororesin layer 10 and the adhesion layer 12 is suppressed. Thus, the circuit board 1 of Embodiment 1 can have excellent reliability.

In the present disclosure, the circuit board is not limited to a board on which a circuit has been formed by processing a metal layer of a substrate. The circuit board according to the present disclosure includes a laminate formed by bonding a substrate or an additional circuit board to a circuit board using a bonding sheet, and a laminate having a connection hole such as a via-hole.

### <Structure>

As illustrated in FIG. 1, a circuit board 1 of Embodiment 1 includes a fluororesin layer 10, an adherend layer 17, and an adhesion layer 12 bonding the fluororesin layer 10 and the adherend layer 17 together. The fluororesin layer 10 has a first main surface 10a facing the adhesion layer 12 and a second main surface 10b opposite to the first main surface 10a. The adherend layer 17 includes a first resin layer 16 and a first metal layer 13 provided on a part of a surface of the first resin layer 16. The first resin layer 16 may be a laminate including a layer, such as a metal layer, a glass cloth layer, or a nonwoven fabric layer, in addition to a resin layer. The resin layer may contain an inorganic filler. As illustrated in FIG. 1, the first main surface 10a may be in close proximity to the adhesion layer 12.

A first-A surface 13a of the first metal layer 13 is a surface opposite to a surface of the first metal layer 13 in contact with the first resin layer 16. A first-B surface 12a of the adhesion layer 12 is a surface opposite to a surface of the adhesion layer 12 in contact with the fluororesin layer 10. The first-A surface 13a is in contact with the first-B surface 12a. At least a part of the first metal layer 13 is embedded in the adhesion layer 12. A third main surface 16a of the first resin layer 16 is a surface facing the first metal layer 13. The region of the third main surface 16a where the first metal layer 13 is not provided is in contact with the adhesion layer 12.

The circuit board 1 further includes a second metal layer 11 disposed on the second main surface 10b of the fluororesin layer 10. The second metal layer 11 is made of a metal. The fluororesin layer 10 and the second metal layer 11 may be in contact with each other. The fluororesin layer 10 and the second metal layer 11 may be bonded together with an adhesive thin film (not illustrated) interposed between the fluororesin layer 10 and the second metal layer 11.

The circuit board 1 further includes a connecting portion 14. The connecting portion 14 is made of a metal and electrically connects the first metal layer 13 and the second metal layer 11 to each other. A through-hole extending through the fluororesin layer 10 and the adhesion layer 12 is formed in the circuit board 1. That is, the fluororesin layer 10 and the adhesion layer 12 have a through-hole extending through the fluororesin layer 10 and the adhesion layer 12. The connecting portion 14 is formed in the through-hole. More specifically, the connecting portion 14 is formed on an inner wall surface of the fluororesin layer 10 defining a part of the through-hole and an inner wall surface defining a part of the adhesion layer 12. The first metal layer 13 defines a bottom surface of the through-hole, and the connecting portion 14 is also formed on the bottom surface.

When the circuit board 1 is viewed from a direction perpendicular to the second main surface 10b, the second metal layer 11 is not formed in a region overlapping the through-hole. The second metal layer 11 has an opening connected to the through-hole. When the circuit board 1 is viewed from the direction perpendicular to the second main surface 10b, the first metal layer 13 is formed in the region overlapping the through-hole. The first metal layer 13 is a via bottom that covers the through-hole.

A cross-sectional area of the through-hole increases continuously from the first metal layer 13 toward the second metal layer 11. In the present disclosure, the cross-sectional area of the through-hole refers to a cross-sectional area when viewed in a cross section perpendicular to a direction from the first metal layer 13 toward the second metal layer 11.

### <Fluororesin Layer>

In Embodiment 1, the fluororesin layer contains polytetrafluoroethylene and a first inorganic filler. Polytetrafluoroethylene has a small dielectric constant and a low dielectric loss tangent. Accordingly, the circuit board in which the fluororesin layer is used as an insulating layer has good high-frequency characteristics.

In Embodiment 1, a volume content of the first inorganic filler in the fluororesin layer is 50% by volume to 66% by volume. According to this, since the fluororesin layer has a low thermal expansion coefficient, dimensional stability is excellent. Moreover, the connecting portion provided on the inner wall surface of the fluororesin layer has excellent electrical connection reliability. The lower limit of the content of the first inorganic filler in the fluororesin layer is 50% by volume or may be 60 by volume, or 63% by volume from the viewpoint of decreasing the thermal expansion coefficient. When the content of the first inorganic filler in the fluororesin layer is 50% by volume or more, the thermal expansion coefficient of the fluororesin layer decreases. When the content is 60% by volume or more, the thermal expansion coefficient further decreases. When the content is 63% by volume or more, the thermal expansion coefficient even further decreases. The upper limit of the content of the first inorganic filler in the fluororesin layer is 66% by volume or may be 65% by volume. When the content of the first inorganic filler in the fluororesin layer is 66% by volume or less, electrical connection reliability of the connecting portion is excellent. When the content is 65% by volume or less, the thermal expansion coefficient, electrical connection reliability of the connecting portion is more excellent. The content of the first inorganic filler in the fluororesin layer may be 60% by volume to 66% by volume, or 63% by volume to 65% by volume.

In the present disclosure, a method for measuring the volume content of the first inorganic filler in the fluororesin layer is as follows. The circuit board is cut by argon ion polishing to expose a cross section of the fluororesin layer. The cross section is a plane perpendicular or parallel to the stacking surface of the circuit board. If the cross section is a plane parallel to the stacking surface of the circuit board, the cross section is likely to have a large area. If the cross section is a plane perpendicular to the stacking surface, the cross section is easily formed. The cross section of the fluororesin layer is observed at a magnification of 10,000 times using a high-resolution scanning electron microscope (SEM) (SU8020, manufactured by Hitachi High-Tech Corporation) at a low accelerating voltage to obtain a SEM image. A rectangular measurement region of 8 μm×12 μm is provided in the SEM image. The content (area percentage) based on the area occupied by the first inorganic filler is measured in this measurement region. The area percentage is measured by extracting portions of the first inorganic filler using multi-value conversion image analysis processing software. For 30 different measurement regions, the area percentages of the first inorganic filler are measured, and the average value of the area percentages is calculated. Next, for a total of 40 measurement regions obtained by adding 10 new measurement regions in which the area percentages have not yet been measured to the measurement regions in which the area percentages have already been measured, the average value of the area percentages of the first inorganic filler is calculated. If the difference between the average value of the area percentages before adding the 10 measurement regions and the average value of the area percentages of the measurement regions after adding the 10 measurement regions is within 1%, the average value of the area percentages of the measurement regions after the addition is taken as the volume content of the first inorganic filler in the fluororesin layer. If the difference is more than 1%, 10 measurement regions in which the area percentages have not yet been measured are added, and the average value of the area percentages of the measurement regions after the addition is calculated. This operation is repeated until the difference between before and after the addition of the measurement regions is within 1%. The average value of the area percentages when the difference between before and after the addition of the measurement regions becomes within 1% is taken as the volume content of the first inorganic filler in the fluororesin layer.

In Embodiment 1, a mass content of the first inorganic filler in the fluororesin layer may be 50% by mass to 67% by mass. According to this, since the fluororesin layer has a low thermal expansion coefficient, dimensional stability is excellent. Moreover, the connecting portion provided on the inner wall surface of the fluororesin layer has excellent electrical connection reliability. The lower limit of the content of the first inorganic filler in the fluororesin layer may be 50% by mass, 60% by mass, or 63% by mass from the viewpoint of decreasing the thermal expansion coefficient. When the content of the first inorganic filler in the fluororesin layer is 50% by mass or more, the thermal expansion coefficient of the fluororesin layer decreases. When the content is 60% by mass or more, the thermal expansion coefficient further decreases. When the content is 63% by mass or more, the thermal expansion coefficient even further decreases. The upper limit of the content of the first inorganic filler in the fluororesin layer may be 67% by mass or 66% by mass. When the content of the first inorganic filler in the fluororesin layer is 67% by mass or less, electrical connection reliability of the connecting portion is excellent. When the content is 67% by mass or less, electrical connection reliability of the connecting portion is more excellent. The content of the first inorganic filler in the fluororesin layer may be 50% by mass to 67% by mass, 60% by mass to 66% by mass, or 63% by mass to 65% by mass.

In the present disclosure, a method for measuring the mass content of the first inorganic filler in the fluororesin layer is as follows. The fluororesin layer is heated in a nitrogen atmosphere with a simultaneous thermogravimetric-differential scanning calorimeter (TG-DSC) to increase the temperature of the fluororesin layer from 30° C. to 700° C. at 20° C./min. An initial weight of the fluororesin layer and a recovery weight of a substance recovered after heating are measured. The ratio of the recovery weight to the initial weight is taken as the mass content of the first inorganic filler in the fluororesin layer.

The first inorganic filler may be a nonmetallic inorganic filler and may contain silica. Silica is cheap and easy to obtain. In addition, the dielectric loss tangent of silica is smaller than the dielectric loss tangents of many other inorganic fillers. Since the dielectric constant of silica is close to dielectric constants of fluororesins, even when the first inorganic filler contains silica in a large amount, the dielectric constant of the first inorganic filler does not change significantly. The content of silica in the first inorganic filler may be 80% by mass or more, 90% by mass or more, or 92% by mass or more from the viewpoint of reducing a decrease in the dielectric loss tangent of the fluororesin layer. The upper limit of the content of silica in the first inorganic filler may be 100% by mass. The content of silica in the first inorganic filler may be 80% by mass to 100% by mass, 90% by mass to 100% by mass, or 92% by mass to 100% by mass from the viewpoint of suppressing a decrease in the dielectric loss tangent of the fluororesin layer.

In the present disclosure, a method for measuring the mass content of silica in the first inorganic filler in the fluororesin layer is as follows. First, the recovery weight of the recovered substance obtained by the above-described method for measuring the mass content of the first inorganic filler in the fluororesin layer is measured. The recovered substance is used to measure the silicon (Si) content in the recovered substance by high-frequency inductively coupled plasma (ICP) spectroscopy. The content of silica in the recovered substance is calculated from the silicon content on the assumption that silica has a composition of SiO₂. This content is the mass content of silica in the first inorganic filler in the fluororesin layer.

The silica in the first inorganic filler may be a natural product or a synthetic product. The silica in the first inorganic filler may be crystalline or amorphous. The silica in the first inorganic filler may be silica produced by a dry process or silica produced by a wet process. The silica in the first inorganic filler may be synthetic silica produced by a dry process in view of availability and quality.

The silica in the first inorganic filler may include spherical silica. According to this, in the manufacturing process of the circuit board, machinability such as drilling is improved. The content of spherical silica in silica may be 80% by mass to 100% by mass, 90% by mass to 100% by mass, or 95% by mass to 100% by mass. When the content of spherical silica in silica is 80% by mass to 100% by mass, the machinability of the circuit board is improved. When the content is 90° % by mass to 100% by mass, the machinability of the circuit board is further improved. When the content is 95% by mass to 100% by mass, the machinability of the circuit board is even further improved. In the present disclosure, spherical silica refers to silica having a sphericity of 0.80 or more.

Spherical silica may have an average particle size of 0.2 μm to 7.0 μm. According to this, the fluororesin layer has a large breaking elongation and excellent mechanical strength and has excellent machinability such as cutting and drilling. The lower limit of the average particle size of spherical silica may be 0.2 μm, 0.5 μm, or 1.0 μm in view of mechanical strength such as breaking elongation. When the average particle size of spherical silica is 0.2 μm or more, the mechanical strength is excellent. When the average particle size is 0.5 μm or more, the mechanical strength of the fluororesin layer is more excellent. When the average particle size is 1.0 μm or more, the mechanical strength of the fluororesin layer is even more excellent. The upper limit of the average particle size of spherical silica may be 7.0 μm, 5.0 μm, or 3.0 μm in view of machinability such as cutting and drilling. When the average particle size of spherical silica is 7.0 μm or less, the machinability of the fluororesin layer is excellent. When the average particle size is 5.0 μm or less, the machinability of the fluororesin layer is more excellent. When the average particle size is 3.0 μm or less, the machinability of the fluororesin layer is even more excellent. The average particle size of spherical silica may be 0.2 μm to 7.0 μm, 0.5 μm to 5.0 μm, or 1.0 μm to 3.0 μm.

In the present disclosure, the average particle size of spherical silica is an average particle size of primary particles. The average particle size is expressed by a mode diameter of a volume particle size distribution. In the present disclosure, a method for measuring an average particle size of spherical silica in the fluororesin layer is as follows. The fluororesin layer is heated in a nitrogen atmosphere with a simultaneous thermogravimetric-differential scanning calorimeter (TG-DSC) to increase the temperature of the fluororesin layer from 30° C. to 700° C. at 20° C./min, thereby obtaining a recovered substance. The recovered substance contains silica. The recovered substance is observed with a SEM. One hundred silica particles are randomly selected, the particle sizes are measured to determine the particle size distribution, and the average particle size is calculated.

The first inorganic filler may contain titanium oxide. Since titanium oxide has a large dielectric constant, the dielectric constant of the fluororesin layer can be adjusted by adding a small amount of titanium oxide to the first inorganic filler. The content of titanium oxide in the first inorganic filler may be 1% by mass or more or 2% by mass or more. The upper limit of the content of titanium oxide in the first inorganic filler may be 20% by mass or 10% by mass. The content of titanium oxide in the first inorganic filler may be 1% by mass to 20% by mass or 2% by mass to 10% by mass.

A method for measuring the mass content of titanium oxide in the first inorganic filler in the fluororesin layer is as follows. First, the recovery weight of the recovered substance obtained by the above-described method for measuring the mass content of the first inorganic filler in the fluororesin layer is measured. The recovered substance is used to measure the titanium (Ti) content in the recovered substance by ICP spectroscopy. The content of titanium oxide in the recovered substance is calculated from the titanium content on the assumption that titanium oxide has a composition of TiO₂. This content is the mass content of titanium oxide in the first inorganic filler.

The first inorganic filler can contain both silica and titanium oxide. According to this, since the dielectric constant of titanium oxide has temperature change characteristics opposite to those of the dielectric constant of silica, the temperature stability of the dielectric constant can be improved.

The first inorganic filler can contain a nonmetallic inorganic filler (hereinafter, also referred to as “another inorganic filler”) other than silica and titanium oxide as long as the effects of the present disclosure are not impaired. In general, an inorganic filler has a small thermal expansion coefficient, therefore, when the first inorganic filler contains another inorganic filler other than silica and titanium oxide, the content of silica or titanium oxide can be reduced depending on the content of the other inorganic filler. Examples of the other inorganic filler include aluminum oxide, magnesium oxide, calcium oxide, talc, barium sulfate, boron nitride, zinc oxide, potassium titanate, glass, and mica. These inorganic fillers may be used alone or in combination of two or more thereof.

The fluororesin layer can be composed of polytetrafluoroethylene, the first inorganic filler, and incidental impurities. The fluororesin layer may contain a resin (another fluororesin) other than polytetrafluoroethylene. That is, the fluororesin layer can be composed of polytetrafluoroethylene, the first inorganic filler, another fluororesin, and incidental impurities. In this case, the upper limit of the content of the other fluororesin may be 10% by mass or 5% by mass.

The fluororesin layer can contain a component other than polytetrafluoroethylene and the first inorganic filler as long as the effects of the present disclosure are not impaired. In the fluororesin layer, the sum of polytetrafluoroethylene, the first inorganic filler, another fluororesin, incidental impurities, and a component that can be contained as long as the effects of the present disclosure are not impaired is taken as 100%, and the contents of polytetrafluoroethylene, etc. are determined.

The fluororesin layer need not necessarily include a glass cloth. In a fluororesin layer that does not include a glass cloth, irregularities are less likely to be generated on the inner wall surface, and electrical connection reliability is excellent in a case of forming a connecting portion on the inner wall surface.

The lower limit of an average thickness of the fluororesin layer may be 20 μm, 40 μm, or 60 μm. If the average thickness is less than 20 μm, the mechanical strength may be insufficient. In addition, dimensional errors have a great influence on high-frequency characteristics of the circuit board, which may result in a difficulty in designing a circuit and manufacturing a circuit component. The upper limit of the average thickness of the fluororesin layer may be 500 μm, 300 μm, or 150 μm. If the average thickness exceeds 500 μm, the thickness of the circuit board may be excessively large. In addition, in a case where the circuit board is required to have flexibility, the flexibility may be insufficient. The average thickness of the fluororesin layer may be 20 μm to 500 μm, 40 μm to 300 μm, or 60 μm to 150 μm.

In the present disclosure, the “average thickness” refers to the distance between an average line of an interface closer to a front surface of the circuit board and an average line of an interface closer to a back surface in a cross section cut in the thickness direction of an object. The “average line” refers to a virtual line drawn along an interface, in which the total area of peaks (total area above the virtual line) and the total area of troughs (total area below the virtual line), the peaks and the troughs being defined by the interface and the virtual line, are equal to each other. The average thickness of each layer described later is also defined in the same manner.

In a fluororesin layer having an area of 1 m², the upper limit of the difference between the maximum value and the minimum value (maximum value−minimum value) of the thickness of the fluororesin layer may be 10 μm, 5 μm, or 2 μm. When the difference is 10 μm or less, 5 μm or less, or 2 μm or less, the circuit design and manufacturing of a circuit component are facilitated. The maximum value and the minimum value of the thickness of the fluororesin layer are measured using an outside micrometer MDH-25 MB manufactured by Mitutoyo Corporation with a terminal surface of the measuring terminal regarded as a “flat surface”.

### <Adhesion Layer>

In order to reduce the transmission loss of a substrate, it is conceivable that a fluororesin is used for an adhesion layer as in a dielectric layer of the substrate. However, since fluororesins have high softening temperatures, a press machine capable of pressing at high temperatures is necessary. In addition, productivity decreases because it takes time to raise the temperature and to perform cooling. Furthermore, thermal shrinkage is large when a fluororesin is cooled to room temperature to be changed from a softened state to a hardened state, and thus dimensional stability is poor. Thus, there is a demand for an adhesion layer that is mainly composed of a resin having a low dielectric loss tangent and that can be bonded at a low temperature.

In Embodiment 1, the adhesion layer contains a resin and a second inorganic filler. The circuit board of Embodiment 1 includes a laminate in which this adhesion layer and the fluororesin layer described above are in contact with each other and bonded together. In this circuit board, even in a case where a through-hole extending through the fluororesin layer and the adhesion layer is formed, the generation of a scooped part near the interface between the fluororesin layer and the adhesion layer is suppressed. In addition, the adhesion layer has excellent adhesion to both the fluororesin layer and an adherend layer. Thus, reliability of the circuit board of Embodiment 1 is improved. A content of a fluororesin in the resin of the adhesion layer is 5% by mass or less. In the resin of the adhesion layer, the content of a fluororesin, which has a high softening temperature, is reduced. Accordingly, this adhesion layer can bond the fluororesin layer and the adherend layer together at a low temperature.

The resin may contain a polyolefin or a polystyrene-based elastomer. According to this, the transmission loss of a circuit is reduced because of a low dielectric loss tangent, and bonding can be performed at a temperature of 180° C. or lower because of a low softening temperature.

The polyolefin is, for example, polyethylene or polypropylene. The polyolefin may be an acid-modified polyolefin. This is because an acid-modified polyolefin has strong adhesion to the fluororesin layer and a metal layer. The acid-modified polyolefin is a polyolefin containing a carboxyl group.

The lower limit of the content of the polyolefin in the resin may be 70% by mass, 80% by mass, or 90 by mass from the viewpoints of reducing the softening temperature of the adhesion layer and obtaining good mechanical strength. The upper limit of the content of the polyolefin in the resin may be 100% by mass or 95% by mass. The content of the polyolefin in the resin may be 70% by mass to 100% by mass, 80% by mass to 97% by mass, or 90% by mass to 95% by mass.

The lower limit of the content of the acid-modified polyolefin in the resin may be 70% by mass, 80% by mass, or 90% by mass from the viewpoints of reducing the softening temperature of the adhesion layer and obtaining good mechanical strength. The upper limit of the content of the acid-modified polyolefin in the resin may be 100% by mass or 95% by mass. The content of the acid-modified polyolefin in the resin may be 70% by mass to 100% by mass, 80% by mass to 97% by mass, or 90% by mass to 95% by mass.

Examples of the polystyrene-based elastomer include styrene-ethylene-butylene-styrene block copolymers (SEBS), styrene-ethylene-propylene-styrene copolymers (SEPS), and styrene-ethylene-ethylene-propylene-styrene block copolymers (SEEPS).

The lower limit of the content of the polystyrene-based elastomer in the resin may be 50% by mass, 55% by mass, or 60% by mass from the viewpoints of reducing the softening temperature of the adhesion layer and obtaining good mechanical strength. The upper limit of the content of the polystyrene-based elastomer in the resin may be 100% by mass or 80% by mass. The content of the polystyrene-based elastomer in the resin may be 50% by mass to 100% by mass, 55% by mass to 90% by mass, or 60% by mass to 80% by mass.

The adhesion layer may contain a resin (another resin) other than the polyolefin and the polystyrene-based elastomer. The other resin is, for example, polyphenylene ether.

In the adhesion layer, the upper limit of the content of the other resin may be 30% by mass, 20% by mass, or 10% by mass when the resin is a polyolefin. In the adhesion layer, the upper limit of the content of the other resin may be 50% by mass, 45% by mass, or 40% by mass when the resin is a polystyrene-based elastomer.

In Embodiment 1, a volume content of the second inorganic filler in the adhesion layer is 29% by volume to 47% by volume. According to this, the length of the scooped part can be made smaller than 25 μm. Since the adhesion layer has a low softening temperature, a high thermal expansion coefficient of the adhesion layer is not a disadvantage. Accordingly, the adhesion layer need not contain the second inorganic filler in order to reduce the thermal expansion coefficient of the adhesion layer. The lower limit of the content of the second inorganic filler in the adhesion layer may be 29% by volume, 33% by volume, or 38% by volume from the viewpoint of further reducing the length of the scooped part. The upper limit of the content of the second inorganic filler in the adhesion layer may be 47% by volume, 43% by volume, or 40% by volume from the viewpoint of maintaining high adhesive strength. The content of the second inorganic filler in the adhesion layer may be 29% by volume to 47% by volume, 33% by volume to 43% by volume, or 38% by volume to 40% by volume.

In the present disclosure, a method for measuring the volume content of the second inorganic filler in the adhesion layer is as follows. The circuit board is cut by argon ion polishing to expose a cross section of the adhesion layer. The cross section is a plane perpendicular or perpendicular to the stacking surface of the circuit board. If the cross section is a plane parallel to the stacking surface of the circuit board, the cross section is likely to have a large area. If the cross section is a plane perpendicular to the stacking surface, the cross section is easily formed. The cross section of the adhesion layer is observed at a magnification of 10,000 times using a high-resolution scanning electron microscope (SEM) (SU8020, manufactured by Hitachi High-Tech Corporation) at a low accelerating voltage to obtain a SEM image. A rectangular measurement region of 5 μm×12 μm is provided in the SEM image. The content (area percentage) based on the area occupied by the second inorganic filler is measured in the measurement region. The area percentage is measured by extracting portions of the second inorganic filler using multi-value conversion image analysis processing software. For 30 different measurement regions, the area percentages of the second inorganic filler are measured, and the average value of the area percentages is calculated. Next, for a total of 40 measurement regions obtained by adding 10 new measurement regions in which the area percentages have not yet been measured to the measurement regions in which the area percentages have already been measured, the average value of the area percentages of the second inorganic filler is calculated. If the difference between the average value of the area percentages before adding the 10 measurement regions and the average value of the area percentages of the measurement regions after adding the 10 measurement regions is within 1%, the average value of the area percentages of the measurement regions after the addition is taken as the volume content of the second inorganic filler in the adhesion layer. If the difference is more than 1%, 10 measurement regions in which the area percentages have not yet been measured are added, and the average value of the area percentages of the measurement regions after the addition is calculated. This operation is repeated until the difference between before and after the addition of the measurement regions is within 1%. The average value of the area percentages when the difference between before and after the addition of the measurement regions becomes within 1% is taken as the volume content of the second inorganic filler in the adhesion layer.

In Embodiment 1, a mass content of the second inorganic filler in the adhesion layer may be 40% by mass to 70% by mass. According to this, the length of the scooped part can be made smaller than 25 μm. The lower limit of the content of the second inorganic filler in the adhesion layer may be 40% by mass, 50% by mass, or 55% by mass. The upper limit of the content of the second inorganic filler in the adhesion layer may be 70% by mass, 67% by mass, or 63% by mass. The content of the second inorganic filler in the adhesion layer may be 40% by mass to 70% by mass, 50% by mass to 67% by mass, or 55% by mass to 63% by mass.

In the present disclosure, a method for measuring the mass content of the second inorganic filler in the adhesion layer is as follows. The adhesion layer is heated in a nitrogen atmosphere with a simultaneous thermogravimetric-differential scanning calorimeter (TG-DSC) to increase the temperature of the adhesion layer from 30° C. to 700° C. at 20° C./min. An initial weight of the adhesion layer and a recovery weight of a substance recovered after heating are measured. The ratio of the recovery weight to the initial weight is taken as the mass content of the second inorganic filler in the adhesion layer.

In the case where the mass content of the first inorganic filler in the fluororesin layer is represented by X (% by mass), and the mass content of the second inorganic filler in the adhesion layer is represented by Y (% by mass), an absolute value Z of the difference between X and Y may be 0 to 17, 0 to 10, or 0 to 7. According to this, the length of the scooped part can be further reduced.

The second inorganic filler may be a nonmetallic inorganic filler and may contain silica. Silica has a relatively low specific gravity. The surface of silica is easily treated with, for example, a silane coupling agent. Accordingly, silica is easily mixed with the resin in the adhesion layer. Silica is cheap and easy to obtain. The content of silica in the second inorganic filler may be 50% by mass to 100% by mass, 70% by mass to 100% by mass, or 90% by mass to 100% by mass.

In the present disclosure, a method for measuring the mass content of silica in the second inorganic filler in the adhesion layer is as follows. First, the recovery weight of the recovered substance obtained by the above-described method for measuring the mass content of the second inorganic filler in the adhesion layer is measured. The recovered substance is used to measure the silicon (Si) content in the recovered substance by ICP spectroscopy. The content of silica in the recovered substance is calculated from the silicon content on the assumption that silica has a composition of SiO₂. This content is the mass content of silica in the second inorganic filler in the adhesion layer.

The second inorganic filler may contain boron nitride. Since boron nitride has a low dielectric constant, even when the second inorganic filler contains a large amount of boron nitride, the dielectric constant of the adhesion layer does not change significantly. In addition, boron nitride has a high thermal conductivity; therefore, incorporation of boron nitride in the second inorganic filler enables heat dissipation performance of the circuit board to be enhanced. The content of boron nitride in the second inorganic filler may be 20% by mass or more, 40% by mass or more, or 60% by mass or more from the viewpoint of enhancing thermal conductivity. The upper limit of the content of boron nitride in the second inorganic filler may be 100% by mass. The content of boron nitride in the second inorganic filler may be 20% by mass to 100% by mass, 40% by mass to 100% by mass, or 60% by mass to 100% by mass.

In the present disclosure, a method for measuring the mass content of boron nitride in the second inorganic filler in the adhesion layer is as follows. First, the recovery weight of the recovered substance obtained by the above-described method for measuring the mass content of the second inorganic filler in the adhesion layer is measured. The recovered substance is used to measure the boron content in the recovered substance by ICP spectroscopy. The content of boron nitride in the recovered substance is calculated from the boron content on the assumption that boron nitride has a composition of BN. This content is the mass content of boron nitride in the second inorganic filler in the adhesion layer.

The second inorganic filler can contain both silica and boron nitride. According to this, the generation of a scooped part can be suppressed, and heat dissipation performance of the circuit board can be enhanced. In addition, even when the second inorganic filler contains silica and boron nitride in a large amount, the dielectric constant of the adhesion layer does not change significantly.

The second inorganic filler can contain a nonmetallic inorganic filler (hereinafter, also referred to as “another inorganic filler”) other than silica and boron nitride as long as the effects of the present disclosure are not impaired. Examples of the other inorganic filler include titanium nitride, aluminum oxide, magnesium oxide, calcium oxide, talc, barium sulfate, boron nitride, zinc oxide, potassium titanate, glass, and mica. These other inorganic fillers may be used alone or in combination of two or more thereof.

The adhesion layer can be composed of the resin, the second inorganic filler, and incidental impurities. The adhesion layer can contain a component other than the resin and the second inorganic filler as long as the effects of the present disclosure are not impaired. Examples of the component other than the resin and the second inorganic filler include a flame retardant, a flame retardant assistant, a pigment, an antioxidant, a reflection-imparting agent, a masking agent, a lubricant, a processing stabilizer, a plasticizer, and a foaming agent. The adhesion layer may contain one of these components or two or more of these components. The upper limit of the content of the component in the adhesion layer may be 25% by mass or 10% by mass.

The adhesion layer may have a ratio A/B of an elastic modulus A at 160° C. to an elastic modulus B at 20° C. of 0.08 or less. According to this, the adhesion layer can fill a gap between circuits formed of metal layers even when pressed at a temperature of 180° C. or lower. In addition, the adhesion layer and a metal layer are in close contact with each other, and the adhesive strength between the adhesion layer and the metal layer is improved. The upper limit of the ratio A/B may be 0.08, 0.05, or 0.02 from the viewpoint of ensuring adhesiveness. The lower limit of the ratio A/B may be 0.0001, 0.0005, or 0.001. The ratio A/B may be 0.0001 to 0.08, 0.0005 to 0.05, or 0.001 to 0.02.

In the present disclosure, a method for measuring the elastic modulus B of the adhesion layer at 20° C. and the elastic modulus A at 160° C. is as follows. While vibrations at a frequency of 1 Hz are applied to a bonding sheet constituting the adhesion layer, the bonding sheet is heated to increase the temperature of the bonding sheet from 15° C. to 170° C. at 10° C./min using a dynamic mechanical analyzer (DMS), and the elastic moduli at 20° C. and 160° C. are measured.

The glass transition temperature of the adhesion layer may be 160° C. or lower. According to this, adhesiveness is improved when the fluororesin layer and the metal layer are bonded together by pressing at a temperature of 180° C. lower. The upper limit of the glass transition temperature of the adhesion layer may be 160° C., 150° C., 120° C., or 100° C. When the glass transition temperature of the adhesion layer is 150° C. or lower, the adhesiveness is further improved. When the glass transition temperature is 120° C. or lower, the adhesiveness is even further improved. When the glass transition temperature is 100° C. or lower, the adhesiveness is even still further improved. The lower limit of the glass transition temperature of the adhesion layer may be 10° C. When the glass transition temperature of the adhesion layer is 10° C. or higher, heat resistance is improved. Thus, in reflow soldering or high-temperature reliability evaluation of the circuit board, the possibility of generation of a blister in the adhesion layer or the possibility of peeling of the adhesion layer is reduced. The glass transition temperature of the adhesion layer may be 30° C. to 160° C., 30° C. to 150° C., or 30° C. to 120° C. When the adhesion layer has a plurality of glass transition temperatures, among the glass transition temperatures due to resins whose volume ratio to the total volume of all resins is 10% or more, the highest glass transition temperature is taken as the glass transition temperature of the adhesion layer.

In the present disclosure, a method for measuring the glass transition temperature of the adhesion layer is as follows. The glass transition temperature of the adhesion layer is measured with a dynamic mechanical analyzer (DMS). While vibrations at a frequency of 1 Hz are applied to bonding constituting the adhesion layer, the bonding sheet is heated to increase the temperature of the bonding sheet from 15° C. to 170° C. at 10° C./min. A complex modulus of the bonding sheet is measured within this temperature range, the phase angle is denoted by δ, and the temperature at which tan δ peaks is considered as the glass transition temperature.

The lower limit of the average thickness of the adhesion layer may be 5 μm, 20 μm, or 30 μm in view of adhesiveness. The upper limit of the average thickness of the adhesion layer may be 100 μm, 70 μm, or 50 μm from the viewpoint of finishing the laminate so as to have a small thickness. The average thickness of the adhesion layer may be 5 μm to 100 μm, 20 μm to 70 μm, or 30 μm to 50 μm.

The average thickness of the adhesion layer may be equal to or larger than the thickness of a circuit from the viewpoint of filling a gap between circuits. The average thickness of the adhesion layer may be 10 μm or more larger than the thickness of the circuit, or may be 20 μm or more larger than the thickness of the circuit.

According to Embodiment 1, even in the case where a through-hole extending through the fluororesin layer 10 and the adhesion layer 12 is formed, on the inner wall surface of the fluororesin layer and the inner wall surface of the adhesion layer, the generation of a scooped part near the interface between the fluororesin layer 10 and the adhesion layer 12 is suppressed. Even when a scooped part is generated in the fluororesin layer, the length of the scooped part can be made very small. In the circuit board of Embodiment 1, at least one of the inner wall surface of the fluororesin layer and the inner wall surface of the adhesion layer has a scooped part. The length of the scooped part may be less than 25 μm, less than 20 μm, or less than 15 μm. In the circuit board of Embodiment 1, the inner wall surface of the fluororesin layer and the inner wall surface of the adhesion layer need not necessarily have a scooped part.

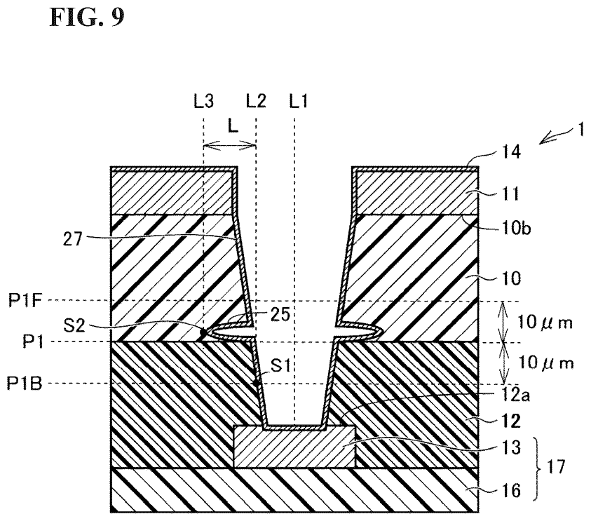

A method for measuring the length of a scooped part in the present disclosure will be described with reference to FIG. 9. First, a circuit board 1 is cut along a plane including a central axis L1 of a through-hole to expose a cross section of a laminate of a fluororesin layer 10 and an adhesion layer 12. In FIG. 9, the central axis L1 corresponds to a line connecting the center (geometric center) of the opening of the through-hole at the second main surface 10b of the fluororesin layer 10 and the center (geometric center) of the opening of the through-hole at the first-B surface 12a of the adhesion layer 12.

Hereinafter, the method for measuring the length of a scooped part will be described in this cross section. An interface between the fluororesin layer 10 and the adhesion layer 12 is defined as an interface P1. A straight line located between the interface P1 and the fluororesin layer 10, parallel to the interface P1, and located at a position at which a distance from the interface P1 is 10 μm is defined as a straight line PIF. A straight line located between the interface P1 and the adhesion layer 12, parallel to the interface P1, and located at a position at which a distance from the interface P1 is 10 μm is defined as a straight line P1B. A scooped part present in a region between the interface P1 and the straight line P1F or a region between the interface P1 and the straight line P1F is specified. In FIG. 9, a scooped part 25 is present in the region between the interface P1, the interface P1 and the straight line P1F. When an interface has irregularities, the interface is defined by an average line thereof. The “average line” refers to a virtual line drawn along an interface in a cross section, in which the total area of peaks (total area above the virtual line) and the total area of troughs (total area below the virtual line), the peaks and the troughs being defined by the interface and the virtual line, are equal to each other.

In a region between the straight line P1F and the straight line P1B of the cross section, a point S1 of an inner wall surface 27 closest to the central axis L1 is specified. Furthermore, an end S2 of the scooped part at a position farthest from the central axis L1 is specified. A straight line perpendicular to the interface P1 and passing through the point S1 is a straight line L2. A straight line parallel to L2 and passing through the end S2 of the scooped part is a straight line L3. A distance L between the straight line L2 and the straight line L3 is measured. The distance L is the length of the scooped part.

### <Adherend Layer>

In Embodiment 1, the adherend layer 17 may include a first resin layer 16 and a first metal layer 13 provided on a part of a surface of the first resin layer 16. In FIG. 1, the adherend layer 17 includes the first metal layer 13 and the first resin layer 16. The first metal layer 13 is made of a metal. The first metal layer 13 is provided so as to be closer to the first main surface 10a of the fluororesin layer 10 than the first resin layer 16. The positional relationship between the first resin layer 16 and the first metal layer 13 may be reversed. Specifically, the first resin layer 16 may be provided so as to be closer to the first main surface 10a than the first metal layer 13.

### <First Metal Layer>

In Embodiment 1, the first metal layer 13 forms an electric circuit. In the present disclosure, the electric circuit includes an antenna.

The first metal layer may contain copper. Copper has a low resistance and a low transmission loss. The content of copper in the first metal layer may be 90% by mass to 100% by mass, 95% by mass to 100% by mass, or 99% by mass to 100% by mass. The first metal layer may be a layer composed of copper and incidental impurities.

The first metal layer can contain a metal other than copper. Examples of metals other than copper include silver, nickel, cobalt, zinc, and chromium. These metals may be used alone or in combination of two or more thereof.

The average thickness of the first metal layer may be 1 μm or more, 5 μm or more, or 10 μm or more from the viewpoint of reducing the electrical resistance. The upper limit of the average thickness of the first metal layer may be 100 μm, 70 μm, or 50 μm in view of the ease of manufacture. The average thickness of the first metal layer may be 1 μm to 100 μm, 5 μm to 70 μm, or 10 μm to 50 μm.

The upper limit of the maximum height (Rz) of surface roughness of a surface of the first metal layer facing the first resin layer may be 2 μm or 1 μm. When the maximum height (Rz) of surface roughness is 2 μm or less, irregularities of a portion where high-frequency signals are concentrated by the skin effect are small, a current is likely to flow linearly. Thus, the transmission loss can be reduced to further improve high-frequency characteristics of the circuit board. The “maximum height (Rz) of surface roughness” refers to a maximum height roughness measured in accordance with JIS-B-0601 (1982). Specifically, the maximum height (Rz) of surface roughness is measured using a laser microscope VK-X200 manufactured by Keyence Corporation.

### <First Resin Layer>

In Embodiment 1, the first resin layer 16 may contain an epoxy resin and a glass cloth. According to this, the circuit board can be manufactured at a low cost. The dielectric loss tangent of the first resin layer 16 may be 0.01 or less, 0.005 or less, or 0.002 or less. According to this, the transmission loss in the first metal layer is reduced, and excellent high-frequency characteristics are obtained. The first resin layer 16 may contain a fluororesin and an inorganic filler. According to this, the transmission loss in the first metal layer is reduced, and excellent high-frequency characteristics are obtained.

### <Second Metal Layer>

In Embodiment 1, the second metal layer 11 forms an electric circuit. In the present disclosure, the electric circuit includes an antenna.

The second metal layer 11 may contain copper. Copper has a low resistance and a small transmission loss. The content of copper in the second metal layer 11 may be 90% by mass to 100% by mass, 95% by mass to 100% by mass, or 99% by mass to 100% by mass. The second metal layer may be a layer composed of copper and incidental impurities.

The second metal layer 11 can contain a metal other than copper. Examples of metals other than copper include silver, nickel, cobalt, zinc, and chromium. These metals may be used alone or in combination of two or more thereof.

The average thickness of the second metal layer 11 may be 1 μm or more, 5 μm or more, or 10 μm or more from the viewpoint of reducing the electrical resistance. The upper limit of the average thickness of the second metal layer 11 may be 100 μm, 70 μm, or 50 μm in view of the ease of manufacture. The average thickness of the second metal layer 11 may be 1 μm to 100 μm, 5 μm to 70 μm, or 10 μm to 50 μm.

### <Connecting Portion>

In Embodiment 1, the connecting portion 14 forms a via-hole. In FIG. 1, the connecting portion 14 is formed on an end face of the second metal layer 11 defining a part of the through-hole, a region near the through-hole of an outer surface of the second metal layer 11, the inner wall surfaces of the fluororesin layer 10 and the adhesion layer 12, and a surface of the first metal layer 13 near the adhesion layer, the surface defining a part of the through-hole (first-A surface 13a). The position where the connecting portion 14 is formed is not limited to the embodiment illustrated in FIG. 1. It is only necessary that the connecting portion 14 electrically connect the first metal layer 13 and the second metal layer 11 to each other. For example, it is only necessary that the connecting portion 14 be formed in the through-hole. More specifically, it is only necessary that the connecting portion 14 be formed on the inner wall surfaces of the fluororesin layer 10 and the adhesion layer 12, that the connecting portion 14 near the fluororesin layer 10 be in contact with at least a part of the second metal layer 11, and that the connecting portion 14 near the adhesion layer 12 be in contact with at least a part of the first metal layer 13.

The connecting portion may contain copper. According to this, the connecting portion has a high electrical conductivity, and the transmission loss can be reduced.

The connecting portion can contain a metal other than copper. Examples of metals other than copper include silver, nickel, cobalt, zinc, and chromium. These metals may be used alone or in combination of two or more thereof.

The average thickness of the connecting portion may be 1 μm or more, 5 μm or more, or 10 μm or more from the viewpoint of improving electric reliability. The upper limit of the average thickness of the connecting portion may be 100 μm, 50 μm, or 30 μm in view of the ease of manufacture. The average thickness of the connecting portion may be 1 μm to 100 μm, 5 μm to 50 μm, or 10 μm to 30 μm.

In FIG. 1, the cross-sectional area of the through-hole increases continuously from the first metal layer 13 toward the second metal layer 11. The change in the cross-sectional area of the through-hole is not limited to this. The cross-sectional area of the through-hole may be constant or may decrease continuously from the first metal layer 13 toward the second metal layer 11.

### <Adhesive Thin Film>

The circuit board of the embodiment can include an adhesive thin film disposed between the fluororesin layer and the second metal layer. The adhesive thin film can improve adhesion between the fluororesin layer and the second metal layer.

The adhesive thin film may contain a fluororesin. Examples of the resin include perfluoroalkoxy alkanes (PFA) and perfluoroethylene propene copolymers (FEP).

The average thickness of the adhesive thin film may be 3 μm or may be 2 μm or less so as not to interfere with the function of the fluororesin layer.

### <Method of Manufacturing Circuit Board>

A method of manufacturing the circuit board of Embodiment 1 includes holding a laminate in which a fluororesin layer, an adhesion layer, and an adherend layer are stacked in this order at a temperature of 180° C. or lower to soften the adhesion layer, thereby bonding the fluororesin layer and the adherend layer together. According to this, even in the case where a through-hole extending through the fluororesin layer and the adhesion layer is formed, the generation of a scooped part near the interface between the fluororesin layer and the adhesion layer is suppressed.

### Embodiment 2: Method of Manufacturing Circuit Board (1)

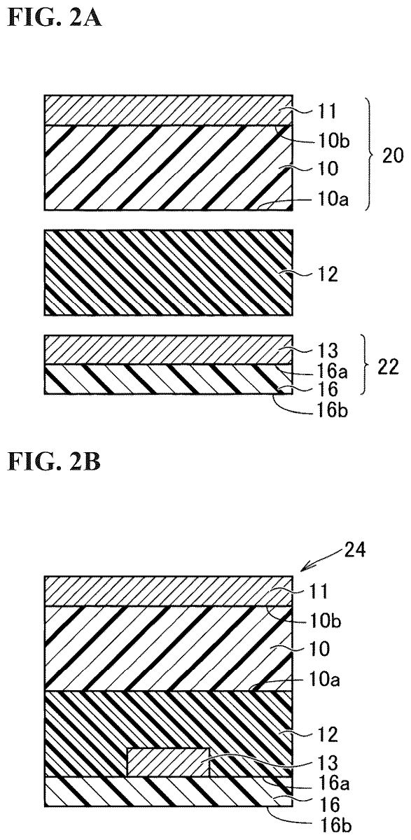

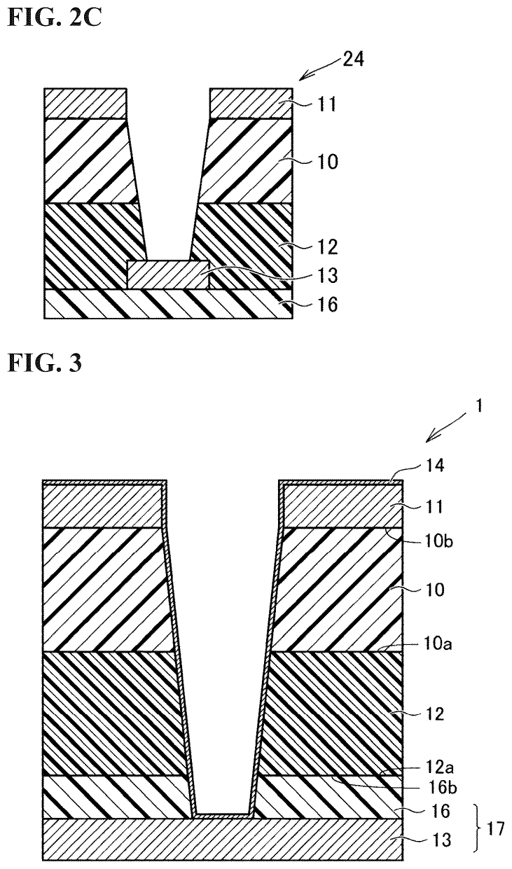

A method of manufacturing a circuit board according to an embodiment (hereinafter, also referred to as “Embodiment 2”) of the present disclosure will be described with reference to FIGS. 1, 2A, 2B, and 2C.

A method of manufacturing a circuit board 1 of Embodiment 2 is a method of manufacturing a circuit board, the method including:
a step of preparing a fluororesin laminate 20 including a fluororesin layer 10 having a first main surface 10a and a second main surface 10b opposite to the first main surface 10a and a second metal layer 11 disposed on the second main surface 10b (hereinafter, also referred to as a “first step”) (refer to FIG. 2A);
a step of preparing a first resin laminate 22 including a first resin layer 16 having a third main surface 16a and a fourth main surface 16b opposite to the third main surface 16a and a first metal layer 13 disposed on the third main surface 16a (hereinafter, also referred to as a “second step”) (refer to FIG. 2A);
a step of preparing an adhesion layer 12 (hereinafter, also referred to as a “third step”) (refer to FIG. 2A);
a step of obtaining a first laminate 24 by stacking the fluororesin laminate 20, the adhesion layer 12, and the first resin laminate 22 in this order such that the first main surface 10a is in contact with the adhesion layer 12 and holding the adhesion layer 12 at a temperature of 180° C. or lower to soften the adhesion layer 12, thereby bonding the fluororesin laminate 20 and the first resin laminate 22 together (hereinafter, also referred to as a “fourth step”) (refer to FIG. 2B);
a step of removing at least a part of the fluororesin layer 10 and at least a part of the adhesion layer 12 to form a through-hole extending through the fluororesin layer 10 and the adhesion layer 12 (hereinafter, also referred to as a “fifth step”) (refer to FIG. 2C); and
a step of forming a connecting portion 14 on an inner wall surface of the fluororesin laminate 20 defining a part of the through-hole and an inner wall surface of the adhesion layer 12 defining a part of the through-hole to obtain a circuit board 1 (hereinafter, also referred to as a “sixth step”) (refer to FIG. 1),
in which the fluororesin layer 10 contains polytetrafluoroethylene and a first inorganic filler,
a content of the first inorganic filler in the fluororesin layer 10 is 50% by volume to 66% by volume,
the adhesion layer 12 contains a resin and a second inorganic filler,
a content of a fluororesin in the resin is 5% by mass or less, and
a content of the second inorganic filler in the adhesion layer 12 is 29% by volume to 47% by volume.

The fluororesin layer 10, the adhesion layer 12, the first metal layer 13, the second metal layer 11, the first resin layer 16, and the connecting portion 14 in Embodiment 2 can be the same as those in Embodiment 1. The first step, the second step, the third step, the fourth step, the fifth step, and the sixth step will be described below. The order of the first step, the second step, and the third step need not necessarily be this order, and any of these steps may be performed first. The first step, the second step, and the third step may be performed at the same time. After the first, second, and third steps, the fourth step, the fifth step, and the sixth step are performed in this order.

### <First Step>

In the first step, a fluororesin laminate 20 including a fluororesin layer 10 having a first main surface 10a and a second main surface 10b opposite to the first main surface 10a and a second metal layer 11 provided on the second main surface 10b is prepared. Examples of the method for providing the second metal layer 11 on the second main surface 10b include a method in which the fluororesin layer 10 and the second metal layer 11 are subjected to thermocompression bonding by high-temperature pressing, a method in which the fluororesin layer 10 and the second metal layer 11 are bonded together by disposing an adhesive thin film therebetween, a method in which a metal constituting the second metal layer 11 is vapor-deposited on the fluororesin layer 10, and a method in which a metal constituting the second metal layer 11 is plated on the fluororesin layer 10.

The first step (step of preparing the fluororesin laminate) can further include a step of forming a second circuit on the fluororesin laminate 20 by etching at least a part of the second metal layer 11. Examples of the method for etching at least a part of the second metal layer 11 include publicly known etching methods such as a wet etching method in which, after formation of a resist pattern, the laminate is immersed in a chemical liquid containing an acid or an alkali and a dry etching method using an ion beam.

### <Second Step>

In the second step, a first resin laminate 22 including a first resin layer 16 having a third main surface 16a and a fourth main surface 16b opposite to the third main surface 16a and a first metal layer 13 provided on the third main surface 16a is prepared.

Examples of the method for providing the first metal layer 13 on one of the main surfaces of the first resin layer 16 include a method in which the first resin layer 16 and the first metal layer 13 are subjected to thermocompression bonding by high-temperature pressing, a method in which the first resin layer 16 and the first metal layer 13 are bonded together by disposing an adhesive thin film therebetween, a method in which a metal constituting the first metal layer 13 is vapor-deposited on the first resin layer 16, and a method in which a metal constituting the first metal layer 13 is plated on the first resin layer 16.

The second step (step of preparing the first resin laminate) may further include a step of forming a first circuit on the first resin laminate 22 by etching at least a part of the first metal layer 13. Examples of the method for etching at least a part of the first metal layer 13 include publicly known etching methods such as a wet etching method in which, after formation of a resist pattern, the laminate is immersed in a chemical liquid containing an acid or an alkali and a dry etching method using an ion beam.

### <Third Step>

In the third step, an adhesion layer 12 is prepared.

### <Fourth Step>

In the fourth step, the fluororesin laminate 20, the adhesion layer 12, and the first resin laminate 22 are stacked in this order such that the first main surface 10a is in contact with the adhesion layer 12, and the adhesion layer 12 is held at a temperature of 180° C. or lower to soften the adhesion layer 12, thereby bonding the fluororesin laminate 20 and the first resin laminate 22 together to obtain a first laminate 24. In Embodiment 2, in the stacking, the first metal layer 13 is disposed so as to be in contact with the adhesion layer 12.

The temperature at which the adhesion layer is held may be 140° C. to 180° C., or 160° C. to 180° C. Heat may be applied to the adhesion layer while a pressure is applied to the laminate of the fluororesin laminate 20, the adhesion layer 12, and the first resin laminate 22. The pressure may be 0.5 MPa to 8 MPa, 1 MPa to 6 MPa, or 3 MPa to 5 MPa. The time during which the adhesion layer is held at the above temperature and the above pressure is applied to the laminate may be 20 minutes to 120 minutes.

The fourth step (step of forming the first laminate) can further include a step of forming a second circuit on the fluororesin laminate 20 by etching at least a part of the second metal layer 11. Examples of the method for etching at least a part of the second metal layer 11 include publicly known etching methods such as a wet etching method in which, after formation of a resist pattern, the laminate is immersed in a chemical liquid containing an acid or an alkali and a dry etching method using an ion beam. The second circuit may be formed in the first step or the fourth step.

### <Fifth Step>

In the fifth step, at least a part of the fluororesin layer 10 and at least a part of the adhesion layer 12 are removed to form a through-hole extending through the fluororesin layer 10 and the adhesion layer 12.

First, a dry film is attached to the second metal layer 11 and exposed, and the second metal layer 11 is etched. The dry film is then stripped to form an opening in the second metal layer 11. Laser processing is performed from the opening on the fluororesin layer 10 and the adhesion layer 12 using the region other than the opening of the second metal layer 11 as a mask (shielding layer). This removes at least a part of the fluororesin layer 10 and at least a part of the adhesion layer 12 to form the opening of the second metal layer 11 and a through-hole extending through the fluororesin layer 10 and the adhesion layer 12. The second metal layer 11 may serve as a laser shielding layer. The use of the second metal layer 11 as the laser shielding layer enables the shape of the through-hole to be controlled.

CO₂ laser may be used for the laser processing. The use of CO₂ laser allows the second metal layer 11 to be easily used as the laser shielding layer.

In FIG. 2C, the through-hole does not extend through the first metal layer 13 and is a blind via-hole.

The first metal layer 13 may be provided on the third main surface 16a of the first resin layer 16. In this structure, since the distance between the first metal layer 13 and the second metal layer 11 is small, wiring lines can be arranged at a high density. In this case, a circuit formed in the first metal layer 13 is embedded in the adhesion layer 12.

In a circuit board that makes use of highly functional characteristics of a fluororesin layer, for example, a circuit board on which a high-frequency antenna is formed, the fluororesin layer is often provided near the surface. Therefore, a manufacturing method in which a general-purpose circuit board is produced first, and a highly functional fluororesin layer is formed on the surface of the circuit board is reasonable in view of the ease of circuit design and the manufacturing cost. A circuit board in which the opening of the blind via-hole is provided on the second main surface 10b of the fluororesin layer 10 and the first metal layer 13 provided on the third main surface 16a of the first resin layer 16 serves as a via bottom of the blind via-hole is easily applied to this reasonable manufacturing method. However, in such a circuit board in which the first metal layer 13 serves as the via bottom of the blind via-hole, when a through-hole is formed by laser processing, laser is reflected at the first metal layer 13. Therefore, the length of a scooped part near the interface between the fluororesin layer 10 and the adhesion layer 12 is larger than that of a circuit board without reflection of laser. According to the present disclosure, even in a circuit board in which the first metal layer serves as a via bottom of a blind via-hole, the length of a scooped part can be reduced. Thus, the present disclosure is particularly effective for a circuit board in which the first metal layer serves as a via bottom of a blind via-hole.

After the formation of the through-hole, a pretreatment step may be performed on the inner wall surfaces of the fluororesin layer 10 and the adhesion layer 12 to clean the inner wall surfaces. Examples of a surface treatment include a potassium permanganate treatment, an alkali treatment, and a plasma treatment.

The alkali treatment is a treatment of etching the surface layers of the inner wall surfaces of the fluororesin layer 10 and the adhesion layer 12 by immersing the first laminate 24 in a solution of a strong alkali such as potassium hydroxide.

The plasma treatment is a treatment of etching the surface layers of the inner wall surfaces by bringing plasma into contact with the inner wall surfaces of the fluororesin layer 10 and the adhesion layer 12. In an atmospheric pressure plasma treatment, which is an example of the plasma treatment, a plasma gas of oxygen, nitrogen, hydrogen, argon, ammonia, or the like is injected on the inner wall surfaces. The first laminate 24 may be placed in a plasma gas atmosphere so that the entire surface of the first laminate 24 is subjected to a plasma treatment. In the plasma treatment, plasma of an inert gas containing a compound having a hydrophilic group may be used.

### <Sixth Step>

In the sixth step, a connecting portion 14 is formed on inner wall surfaces of the fluororesin laminate 20 and the adhesion layer 12 to obtain a circuit board 1.

In the formation of the connecting portion 14, first, an electroless plating layer is formed, by electroless plating, on an end face of the second metal layer 11 defining a part of the through-hole, a region near the opening (through-hole) of the outer surface of the second metal layer 11, the inner wall surface of the fluororesin layer 10, the inner wall surface of the adhesion layer 12, and a surface of the first metal layer 13 near the adhesion layer, the surface defining a part of the through-hole (first-A surface 13a). Subsequently, a plating layer is formed on the electroless plating layer by an electroplating process. This plating layer is the connecting portion 14.

### Embodiment 3: Circuit Board (2)

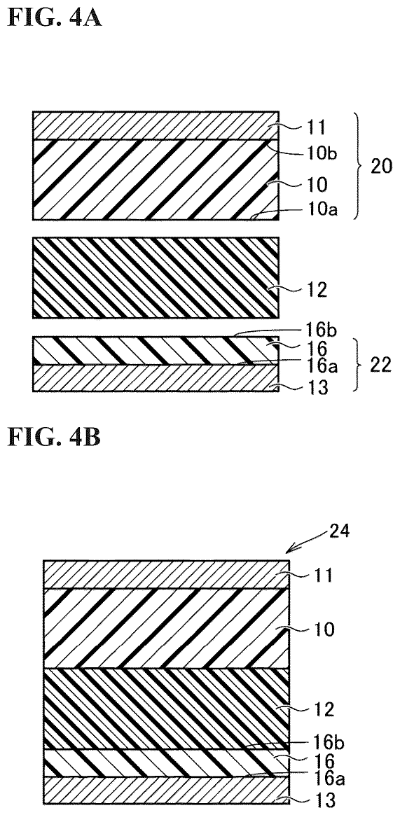

A circuit board according to an embodiment (hereinafter, also referred to as “Embodiment 3”) of the present disclosure and a method of manufacturing the circuit board will be described with reference to FIGS. 3, 4A. 4B, and 4C. As illustrated in FIG. 3, a circuit board 1 of Embodiment 3 includes a fluororesin layer 10, an adherend layer 17, and an adhesion layer 12 bonding the fluororesin layer 10 and the adherend layer 17 together. The fluororesin layer 10 has a first main surface 10a facing the adhesion layer 12 and a second main surface 10b opposite to the first main surface 10a. The adherend layer 17 includes a first resin layer 16 and a first metal layer 13 provided on at least a part of a surface of the first resin layer 16. The first resin layer 16 and the first metal layer 13 may be in contact with each other. The first resin layer 16 and the first metal layer 13 may be bonded to each other with a resin layer, a metal layer, an adhesion layer, or a laminate thereof interposed between the first resin layer 16 and the first metal layer 13.

The circuit board 1 of Embodiment 3 includes the first resin layer 16 disposed between the first metal layer 13 and the adhesion layer 12. A fourth main surface 16b of the first resin layer 16 that is far from the first metal layer 13 is in contact with a first-B surface 12a of the adhesion layer 12 that is far from the fluororesin layer 10.

The circuit board 1 further includes a second metal layer 11 provided on the second main surface 10b of the fluororesin layer 10. The fluororesin layer 10 and the second metal layer 11 may be in contact with each other. The fluororesin layer 10 and the second metal layer 11 may be bonded together with an adhesive thin film (not illustrated) interposed between the fluororesin layer 10 and the second metal layer 11.

The circuit board 1 further includes a connecting portion 14. The connecting portion 14 is made of a metal and electrically connects the first metal layer 13 and the second metal layer 11 to each other. The second metal layer 11, the fluororesin layer 10, the adhesion layer 12, and the first resin layer 16 include a through-hole extending therethrough. The connecting portion 14 is formed in the through-hole. More specifically, the connecting portion 14 is formed on the inner wall surface of the second metal layer 11, the inner wall surface of the fluororesin layer 10, the inner wall surface of the adhesion layer 12, and the inner wall surface of the first resin layer 16. The first metal layer 13 defines a bottom surface of the through-hole, and the connecting portion 14 is also formed on the bottom surface.

When the circuit board 1 is viewed from a direction perpendicular to the second main surface 10b of the fluororesin layer 10, the second metal layer 11 is not formed in a region overlapping the through-hole. The second metal layer 11 has an opening connected to the through-hole. When the circuit board 1 is viewed from the direction perpendicular to the second main surface 10b of the fluororesin layer 10, the first metal layer 13 is formed in the region overlapping the through-hole. The first metal layer 13 is a via bottom that covers the through-hole. The through-hole extending through the fluororesin layer 10 and the adhesion layer 12 extends to the first resin layer 16. The connecting portion 14 formed on the inner wall surfaces of the fluororesin layer 10 and the adhesion layer 12 also extends to the first resin layer 16.

In FIG. 3, the cross-sectional area of the through-hole increases continuously from the first metal layer 13 toward the second metal layer 11.

In Embodiment 3, the fluororesin layer 10, the adhesion layer 12, the first metal layer 13, the second metal layer 11, the first resin layer 16, and the connecting portion 14 can be the same as those in Embodiment 1.

According to the circuit board 1 of Embodiment 3, even in the case where the through-hole extending through and the fluororesin layer 10 and the adhesion layer 12 is formed, the generation of a scooped part of the fluororesin layer 10 is suppressed near the interface between the fluororesin layer 10 and the adhesion layer 12. Thus, the reliability of the circuit board 1 of Embodiment 3 is improved.

### <Manufacturing Method>

A method of manufacturing a circuit board 1 of Embodiment 3 is a method of manufacturing a circuit board, the method including:
a step of preparing a fluororesin laminate 20 including a fluororesin layer 10 having a first main surface 10a and a second main surface 10b opposite to the first main surface 10a and a second metal layer 11 disposed on the second main surface 10b (hereinafter, also referred to as a “first-B step”) (refer to FIG. 4A);
a step of preparing a first resin laminate 22 including a first resin layer 16 having a third main surface 16a and a fourth main surface 16b opposite to the third main surface 16a and a first metal layer 13 disposed on the third main surface 16a (hereinafter, also referred to as a “second-B step”) (refer to FIG. 4A);
a step of preparing an adhesion layer 12 (hereinafter, also referred to as a “third-B step”) (refer to FIG. 4A);
a step of obtaining a first laminate 24 by stacking the fluororesin laminate 20, the adhesion layer 12, and the first resin laminate 22 in this order such that the first main surface 10a is in contact with the adhesion layer 12 and holding the adhesion layer 12 at a temperature of 180° C. or lower to soften the adhesion layer 12, thereby bonding the fluororesin laminate 20 and the first resin laminate 22 together (hereinafter, also referred to as a “fourth-B step”) (refer to FIG. 4B);
a step of removing at least a part of the fluororesin layer 10 and at least a part of the adhesion layer 12 to form a through-hole extending through the fluororesin layer 10 and the adhesion layer 12 (hereinafter, also referred to as a “fifth-B step”) (refer to FIG. 4C); and
a step of forming a connecting portion 14 on inner wall surfaces of the fluororesin laminate 20 and the adhesion layer 12 to obtain a circuit board 1 (hereinafter, also referred to as a “sixth step”) (refer to FIG. 3),
in which the fluororesin layer 10 contains polytetrafluoroethylene and a first inorganic filler,
a content of the first inorganic filler in the fluororesin layer 10 is 50% by volume to 66% by volume.
the adhesion layer 12 contains a resin and a second inorganic filler,
a content of a fluororesin in the resin is 5% by mass or less, and
a content of the second inorganic filler in the adhesion layer 12 is 29% by volume to 47% by volume.

The first-B step, the second-B step, the third-B step of Embodiment 3 can be the same as the first step, the second step, and the third step of Embodiment 2, respectively.

The fourth-B step of Embodiment 3 can be the same as the fourth step of Embodiment 2 except that the first resin layer 16 is stacked so as to be in contact with the adhesion layer 12.

In the fifth-B step of Embodiment 3, at least a part of the second metal layer 11, at least a part of the fluororesin layer 10, at least a part of the adhesion layer 12, and at least a part of the first resin layer 16 are removed to form a through-hole extending through these layers.

The method for forming the through-hole can be the same as the method for forming the through-hole in the fifth step of Embodiment 2. In FIG. 4C, the through-hole does not extend through the first metal layer 13 and is a blind via-hole.

After the formation of the through-hole, a pretreatment step may be performed on the inner wall surfaces of the fluororesin layer 10, the adhesion layer 12, and the first resin layer. The pretreatment step can be the same as the pretreatment step of Embodiment 2.

In the sixth-B step of Embodiment 3, the connecting portion 14 is formed on an end face of the second metal layer 11 defining a part of the through-hole, a region near the opening (through-hole) of an outer surface of the second metal layer 11, the inner wall surface of the fluororesin layer 10, the inner wall surface of the adhesion layer 12, the inner wall surface of the first resin layer 16, and a surface of the first metal layer 13 near the adhesion layer, the surface defining a part of the through-hole, to obtain the circuit board 1. The connecting portion 14 can be formed by electroless plating and electroplating in Embodiment 2.

### Embodiment 4: Circuit Board (3)

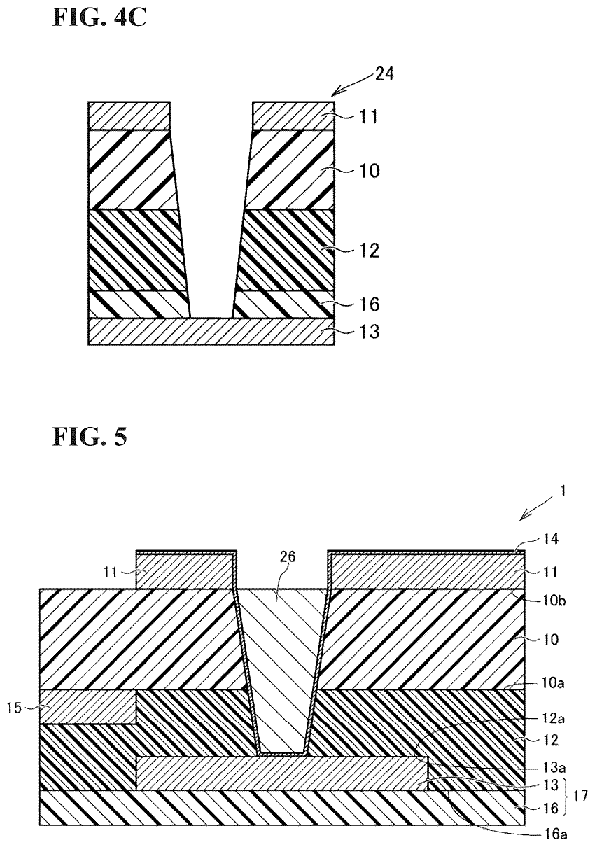

A circuit board according to an embodiment (hereinafter, also referred to as “Embodiment 4”) of the present disclosure and a method of manufacturing the circuit board will be described with reference to FIG. 5. A circuit board 1 of Embodiment 4 is basically the same as the circuit board of Embodiment 1. Differences from the circuit board of Embodiment 1 are that the circuit board 1 of Embodiment 4 includes a filling portion 26 and includes a third metal layer 15. The filling portion 26 fills a through-hole formed in a fluororesin layer 10 and an adhesion layer 12, and is in contact with a connecting portion 14. The third metal layer 15 is disposed on a first main surface 10a of the fluororesin layer 10 and embedded in the adhesion layer 12.

The filling portion 26 may contain a resin. According to this, the electrical connection reliability of the connecting portion can be enhanced because stresses applied to the connecting portion, for example, stresses due to thermal expansion and contraction of the circuit board and vibrations from the outside can be relaxed. The filling portion 26 containing a resin can be easily formed by, for example, screen-printing a paste-like material.

The filling portion 26 may be formed by filling the through-hole with a metal by a plating process. According to this, the electrical connection reliability of the connecting portion can be enhanced because stresses applied to the connecting portion, for example, stresses due to thermal expansion and contraction of the circuit board and vibrations from the outside can be relaxed. The filling by the plating process can be easily performed using the connecting portion 14, and thus the filling portion 26 can be efficiently manufactured.

The third metal layer 15 forms an electric circuit. The third metal layer 15 can have the same configuration as the first metal layer 13.

A method of manufacturing a circuit board of Embodiment 4 is basically the same as the method of manufacturing a circuit board of Embodiment 2. Differences from the method of manufacturing a circuit board of Embodiment 2 will be described below.

In Embodiment 4, in the first step of Embodiment 2, a fluororesin laminate 20 including a fluororesin layer 10 having a first main surface 10a and a second main surface 10b opposite to the first main surface 10a, a second metal layer 11 provided on the second main surface 10b, and a third metal layer 15 provided on the first main surface 10a is prepared, and at least a part of the second metal layer 11 and at least a part of the third metal layer 15 are etched to form circuits on the second main surface 10b and the first main surface 10a.

In Embodiment 4, after the sixth step of Embodiment 2, a step of filling a through-hole in the fluororesin layer 10 and an adhesion layer 12 with, for example, a resin to form a filling portion 26 in contact with a connecting portion 14 is performed. Thus, the circuit board 1 of Embodiment 4 can be obtained.

### Embodiment 5: Circuit Board (4)

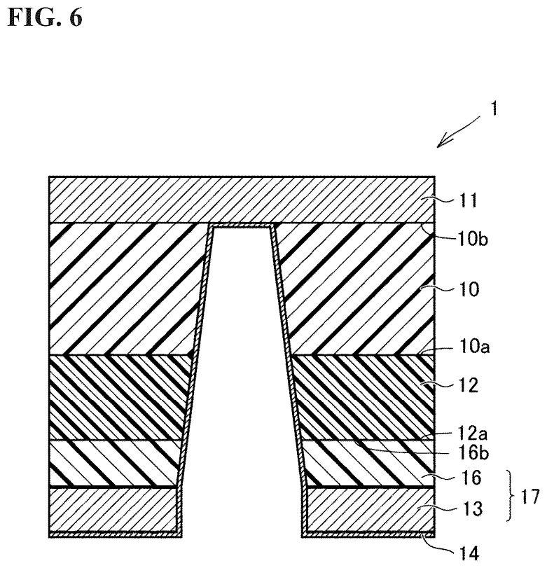

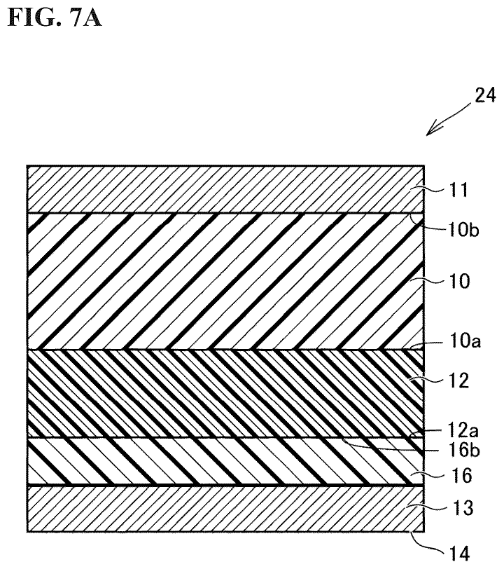

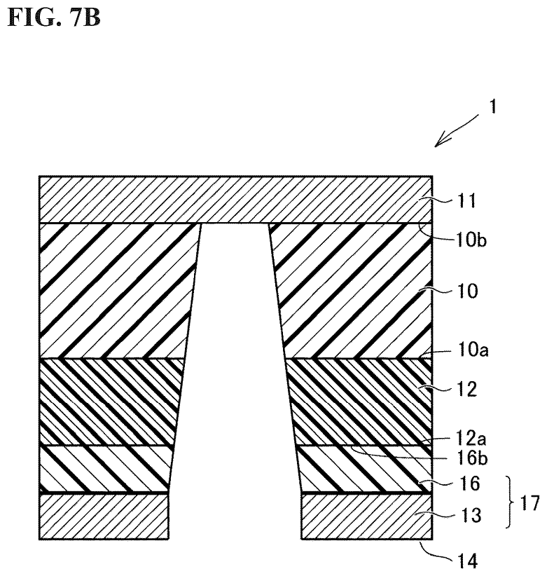

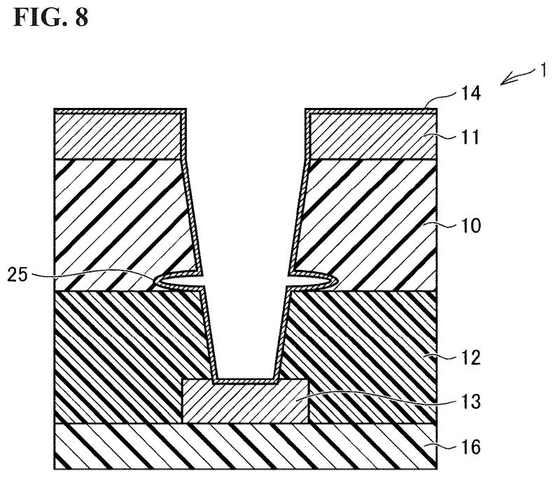

A circuit board according to an embodiment (hereinafter, also referred to as “Embodiment 5) of the present disclosure and a method of manufacturing the circuit board will be described with reference to FIGS. 6, 7A, and 7B. A circuit board 1 of Embodiment 5 includes a fluororesin layer 10, an adherend layer 17, and an adhesion layer 12 bonding the fluororesin layer 10 and the adherend layer 17 together. The fluororesin layer 10 has a first main surface 10a facing the adhesion layer 12 and a second main surface 10b opposite to the first main surface 10a. The adherend layer 17 is formed of a first metal layer 13 and a first resin layer 16.

A fourth main surface 16b of the first resin layer 16 is in contact with a first-B surface 12a of the adhesion layer 12 that is far from the fluororesin layer 10.

The circuit board 1 further includes a second metal layer 11 provided on the second main surface 10b of the fluororesin layer 10. The fluororesin layer 10 and the second metal layer 11 may be in contact with each other. The fluororesin layer 10 and the second metal layer 11 may be bonded together with an adhesive thin film (not illustrated) interposed between the fluororesin layer 10 and the second metal layer 11.

The circuit board 1 further includes a connecting portion 14. The connecting portion 14 is made of a metal and electrically connects the first metal layer 13 and the second metal layer 11 to each other. A through-hole extending through the first resin layer 16, the fluororesin layer 10, and the adhesion layer 12 is formed in the circuit board 1. That is, the first resin layer 16, the fluororesin layer 10, and the adhesion layer 12 have a through-hole extending therethrough. The connecting portion 14 is formed in the through-hole. More specifically, the connecting portion 14 is formed on the inner wall surface of the fluororesin layer 10, the inner wall surface of the adhesion layer 12, the inner wall surface of the first resin layer 16, an end face of the first metal layer, and a region near the through-hole of an outer surface of the first metal layer. The second metal layer 11 defines a bottom surface of the through-hole, and the connecting portion 14 is also formed on the bottom surface.

When the circuit board 1 is viewed from a direction perpendicular to the first main surface 10a, the first metal layer 13 is not formed in a region overlapping the through-hole. The first metal layer 13 has an opening connected to the through-hole. When the circuit board 1 is viewed from the direction perpendicular to the first main surface 10a, the second metal layer 11 is formed in the region overlapping the through-hole. The second metal layer 11 is a via bottom that covers the through-hole.

The cross-sectional area of the through-hold decreases continuously from the first metal layer 13 toward the second metal layer 11.

A method of manufacturing a circuit board of Embodiment 5 is basically the same as the method of manufacturing a circuit board of Embodiment 2. Differences from the method of manufacturing a circuit board of Embodiment 2 will be described below.

A first laminate 24 is obtained as in the first step to the fourth step of Embodiment 2 (refer to FIG. 7A). In Embodiment 5, in the fifth step of Embodiment 2, an opening is formed in the first metal layer 13. Laser processing is performed from the opening on the first resin layer 16, the adhesion layer 12, and the fluororesin layer 10 using the region other than the opening of the first metal layer 13 as a mask. As a result, at least a part of the first resin layer 16, at least a part of the adhesion layer 12, and at least a part of the fluororesin layer 10 are removed, and a through-hole extending from the opening through the first resin layer 16, the adhesion layer 12, and the fluororesin layer 10 is formed (refer to FIG. 7B). That is, the first resin layer 16, the fluororesin layer 10, and the adhesion layer 12 have a through-hole extending therethrough.

In Embodiment 5, in the sixth step of Embodiment 2, first, an electroless plating layer is formed, by electroless plating, on an end face of the first metal layer 13 defining a part of the through-hole, a region near the opening (through-hole) of the outer surface of the first metal layer 13, inner wall surfaces of the fluororesin layer 10 and the adhesion layer 12, and a surface of the second metal layer 11 near the adhesion layer, the surface defining a part of the through-hole. Subsequently, a plating layer is formed on the electroless plating layer by an electroplating process (refer to FIG. 6). This plating layer is the connecting portion 14.

In Embodiment 5, a layer in contact with the second metal layer 11 serving as the via bottom of the blind via-hole (layer that receives more reflected energy from the second metal layer 11) in laser processing is the fluororesin layer 10, which has excellent heat resistance. Thus, the length of a scooped part becomes smaller.

### EXAMPLES

Embodiments will be more specifically described by way of Examples. However, the embodiments are not limited by these Examples.

### [Preparation of Test Laminates]

### <Sample 1 to Sample 16>

Fluororesin laminates 20 each including a fluororesin layer 10 and a second metal layer 11 provided on a main surface of the fluororesin layer as illustrated in FIG. 2A were prepared.

The fluororesin laminates 20 were produced by the following procedure. Materials in the “Fluororesin layer” rows of “Materials” in Tables 1 and 2 were mixed in the mass ratios described in Tables 1 and 2 to prepare mixtures. For example, in Sample 6, a polytetrafluoroethylene powder (denoted as “PTFE” in Tables 1 and 2), silica, and titanium oxide were mixed in a mass ratio of 100:190:10. Next, naphtha was mixed in an amount of 17% by mass relative to the total mass of the polytetrafluoroethylene powder, the silica, and the titanium oxide. The resulting mixture was molded into a sheet and then dried in a thermostatic chamber to remove the naphtha to obtain a fluororesin sheet (corresponding to the fluororesin layer 10) with an average thickness of 130 μm. Next, a perfluoroalkoxy alkane layer with an average thickness of 2 μm was formed on one surface of a copper foil (corresponding to the second metal layer) with an average thickness of 18 μm. This copper foil and the fluororesin sheet are stacked such that the perfluoroalkoxy alkane layer and the fluororesin sheet are in contact with each other. The resulting laminate was heated at 350° C. for 40 minutes while being compressed at a pressure of 4 MPa to obtain a fluororesin laminate 20.

In FIG. 2A, a first resin laminate 22 is formed of a first metal layer 13 and a first resin layer 16; however, in each of the test laminates, the first resin laminate 22 is formed only of the first metal layer 13. The first metal layer 13 is formed of a copper foil with an average thickness of 18 μm.

An adhesion layer 12 was prepared by the following procedure except for Sample 16. Materials in the “Adhesion layer” rows of “Materials” in Tables 1 and 2 were mixed in the mass ratios described in Tables 1 and 2 to prepare mixtures. For example, in Sample 1, an acid-modified polypropylene and an epoxy resin are dissolved in a solvent in a mass ratio of 90:10. This solution and silica were mixed such that a ratio of the acid-modified polypropylene, the epoxy resin, and the silica was 90:10:100 in terms of mass ratio. The solvent is a mixed solvent of methyl ethyl ketone, toluene, ethyl acetate, and cyclohexane in an appropriate ratio, the mixed solvent being capable of dissolving the acid-modified polypropylene and the epoxy resin. A mixture sheet was formed by a doctor blade method and dried to remove the solvent, thereby obtaining a bonding sheet (corresponding to the adhesion layer 12) with an average thickness of 30 μm. The use of the doctor blade method enables the thickness of the mixture sheet to be adjusted. In Tables 1 and 2, “SEEPS” denotes a styrene-ethylene-ethylene-propylene-styrene block copolymer, and “PPE” denotes polyphenylene ether. In Sample 16, a polytetrafluoroethylene powder, a perfluoroalkoxy alkane powder (denoted as “PFA” in Tables 1 and 2), and silica were mixed in a mass ratio of 90:10:80. Next, naphtha was mixed in an amount of 17% by mass relative to the total mass of the polytetrafluoroethylene powder, the perfluoroalkoxy alkane powder, and the silica. The mixture was molded into a sheet and then dried in a thermostatic chamber to remove the naphtha to obtain a bonding sheet (corresponding to the adhesion layer 12) with an average thickness of 30 μm.

The first metal layer 13, the adhesion layer 12, and the fluororesin laminate 20 were stacked in this order such that the fluororesin layer 10 and the first metal layer 13 were in contact with the adhesion layer 12. While the resulting laminate was held at a temperature of 170° C. for 30 minutes, a pressure of 3 MPa was applied. As a result, in Samples 1 to Sample 15, the first metal layer 13 and the fluororesin laminate 20 were bonded together by softening of the adhesion layer 12, and test laminates could be obtained. In the case where a test laminate could be obtained, “Possible” is indicated in the “Whether stacking is possible or not” row in Tables 1 and 2. In Sample 16, the first metal layer 13 and the fluororesin laminate 20 could not be bonded together. In the case where a test laminate could not be obtained, “Impossible” is indicated in the “Whether stacking is possible or not” row in Tables 1 and 2.

TABLE 1

| Sample No. | | | 1 | 2 | 3 | 4 | 5 | 6 | 7 | 8 |
|---|---|---|---|---|---|---|---|---|---|---|
| Materials | Fluororesin | PTFE | 100 | 100 | 100 | 100 | 100 | 100 | 100 | 100 |
| | layer (parts by | Silica | 0 | 100 | 100 | 100 | 100 | 190 | 190 | 190 |
| | mass) | Titanium oxide | 0 | 0 | 0 | 0 | 0 | 10 | 10 | 10 |
| | Adhesion layer | Acid-modified | 90 | 90 | 90 | 90 | 90 | 90 | 90 | 90 |
| | (parts by mass) | polypropylene | | | | | | | | |
| | | Epoxy resin | 10 | 10 | 10 | 10 | 10 | 10 | 10 | 10 |
| | | SEEPS | 0 | 0 | 0 | 0 | 0 | 0 | 0 | 0 |
| | | PPE | 0 | 0 | 0 | 0 | 0 | 0 | 0 | 0 |
| | | PTFE | 0 | 0 | 0 | 0 | 0 | 0 | 0 | 0 |
| | | PFA | 0 | 0 | 0 | 0 | 0 | 0 | 0 | 0 |
| | | Silica | 100 | 0 | 100 | 150 | 0 | 0 | 100 | 150 |
| | | BN | 0 | 0 | 0 | 0 | 100 | 0 | 0 | 0 |
| Fluororesin | Thermal | ppm/° C. | 159 | 83 | 83 | 83 | 83 | 21 | 21 | 21 |
| layer | expansion | Evaluation | C | B | B | B | B | A | A | A |
| | coefficient | | | | | | | | | |
| | First inorganic | % by mass | 0 | 50 | 50 | 50 | 50 | 67 | 67 | 67 |
| | filler content | % by volume | 0 | 50 | 50 | 50 | 50 | 66 | 66 | 66 |
| Adhesion | Second | % by mass | 50 | 0 | 50 | 60 | 50 | 0 | 50 | 60 |
| layer | inorganic filler | % by volume | 29 | 0 | 29 | 39 | 29 | 0 | 29 | 39 |
| | content | | | | | | | | | |
| | Glass transition | ° C. | 64 | 64 | 64 | 64 | 64 | 64 | 64 | 64 |
| | temperature | | | | | | | | | |
| | A/B | | 0.02 | 0.01 | 0.02 | 0.01 | 0.05 | 0.01 | 0.02 | 0.01 |
| | Z | | 50 | 50 | 0 | 10 | 0 | 67 | 17 | 7 |
| Whether stacking is possible or not | | | Possible | Possible | Possible | Possible | Possible | Possible | Possible | Possible |
| Test | Peel strength | N/cm | 20 | 16 | 10 | 8 | 7 | 22 | 20 | 17 |
| laminate | Length of | μm | 64 | 33 | 13 | 13 | 16 | 71 | 14 | 10 |
| | scooped part | Evaluation | C | C | A | A | B | C | A | A |

TABLE 2

| Sample No. | | | 9 | 10 | 11 | 12 | 13 | 14 | 15 | 16 |
|---|---|---|---|---|---|---|---|---|---|---|
| Materials | Fluororesin | PTFE | 100 | 100 | 100 | 100 | 100 | 100 | 100 | 100 |
| | layer (parts by | Silica | 190 | 190 | 190 | 190 | 190 | 190 | 190 | 190 |
| | mass) | Titanium oxide | 10 | 10 | 10 | 10 | 10 | 10 | 10 | 10 |
| | Adhesion layer | Acid-modified | 90 | 90 | 0 | 0 | 90 | 90 | 90 | 0 |
| | (parts by mass) | polypropylene | | | | | | | | |
| | | Epoxy resin | 10 | 10 | 9 | 9 | 10 | 10 | 10 | 0 |
| | | SEEPS | 0 | 0 | 64 | 64 | 0 | 0 | 0 | 0 |
| | | PPE | 0 | 0 | 27 | 27 | 0 | 0 | 0 | 0 |
| | | PTFE | 0 | 0 | 0 | 0 | 0 | 0 | 0 | 90 |
| | | PFA | 0 | 0 | 0 | 0 | 0 | 0 | 0 | 10 |
| | | Silica | 200 | 0 | 0 | 0 | 0 | 100 | 150 | 80 |
| | | BN | 0 | 100 | 0 | 100 | 0 | 0 | 0 | 0 |
| Fluororesin | Thermal | ppm/° C. | 21 | 21 | 21 | 21 | 21 | 21 | 21 | 21 |
| layer | expansion | Evaluation | A | A | A | A | A | A | A | A |
| | coefficient | | | | | | | | | |
| | First inorganic | % by mass | 67 | 67 | 67 | 67 | 67 | 67 | 67 | 67 |
| | filler content | % by volume | 66 | 66 | 66 | 66 | 66 | 66 | 66 | 65 |
| Adhesion | Second | % by mass | 67 | 50 | 0 | 50 | 0 | 50 | 60 | 47 |
| layer | inorganic filler | % by volume | 47 | 29 | 0 | 33 | 0 | 29 | 39 | 47 |
| | content | | | | | | | | | |
| | Glass transition | ° C. | 64 | 64 | 126 | 126 | 64 | 64 | 64 | 110 |
| | temperature | | | | | | | | | |
| | A/B | | 0.02 | 0.05 | 0.03 | 0.03 | 0.01 | 0.02 | 0.01 | 0.5 |
| | Z | | 0 | 17 | 67 | 17 | 67 | 17 | 7 | 20 |
| Whether stacking is possible or not | | | Possible | Possible | Possible | Possible | Possible | Possible | Possible | Impossible |
| Test | Peel strength | N/cm | 10 | 17 | 7 | 5 | 21 | 17 | 12 | <1 |
| laminate | Length of | μm | 10 | 19 | 38 | 14 | 62 | 8 | 7 | — |
| | scooped part | Evaluation | A | B | C | A | C | A | A | — |

### <Measurement of Thermal Expansion Coefficient of Fluororesin Layer>

The thermal expansion coefficient of the fluororesin layer before stacking of each sample was measured. For the measurement, a thermal dilatometer (LIX-2) available from ADVANCE RIKO, Inc. was used, and a linear expansion coefficient of the fluororesin layer in the thickness direction was measured in a range of 20° C. to 120° C. As described above, in the present disclosure, the linear expansion coefficient of the fluororesin layer in the thickness direction is the thermal expansion coefficient of the fluororesin layer. The results are shown in the “Thermal expansion coefficient” row of “Fluororesin lamer” in Tables 1 and 2. In the “Evaluation” row of “Thermal expansion coefficient”, an evaluation of Ais given when the thermal expansion coefficient is less than 40 ppm/° C., an evaluation of B is given when the thermal expansion coefficient is 40 ppm/° C. or more and less than 90 ppm/° C., and an evaluation of C is given when the thermal expansion coefficient is 90 ppm/° C. or more. When the evaluation of A or B is given, it is determined that the thermal expansion coefficient of the fluororesin layer is small. When the evaluation of C is given, it is determined that the thermal expansion coefficient of the fluororesin layer is large.

### <Compositions of Fluororesin Layer and Adhesion Layer>

The volume content (% by volume) and the mass content (% by mass) of the first inorganic filler in the fluororesin layer of each sample are shown in the “% by volume” and “% by mass” rows of “First inorganic filler content” of “Fluororesin layer” in Tables 1 and 2. Among the materials in Tables 1 and 2, silica and titanium oxide correspond to the first inorganic filler. When the sample contains both silica and titanium oxide, the content is calculated on the basis of the total amount of these.

The volume content (% by volume) and the mass content (% by mass) of the second inorganic filler in the adhesion layer of each sample are shown in the “% by volume” and “% by mass” rows of “Second inorganic filler content” of “Adhesion layer” in Tables 1 and 2. Among the materials in Tables 1 and 2, silica and boron nitride correspond to the first inorganic filler. When the sample contains both silica and boron nitride, the content is calculated on the basis of the total amount of these.

On the basis of the mass content X (% by mass) of the first inorganic filler in the fluororesin layer and the mass content Y (% by mass) of the second inorganic filler in the adhesion layer, the absolute value Z of the difference between X and Y was calculated. The results are shown in the “Z” row in Tables 1 and 2.

### <Evaluation of Adhesion Layer>

The glass transition temperature of the adhesion layer of each sample was measured. Furthermore, for the adhesion layer of each sample, the elastic modulus B at 20° C. and the elastic modulus A at 160° C. were measured, and the ratio A/B was calculated. The specific measurement method has been described in Embodiment 1. The results are shown in the “Glass transition temperature” and “A/B” rows of “Adhesion layer” in Tables 1 and 2.

### <Evaluation of Peel Strength>

The evaluation of the peel strength was performed in accordance with JIS-K6854-2 (1999). Specifically, the evaluation was performed by the 180° peel test. A polyimide tape (“P221” manufactured by Nitto Denko Corporation) with a thickness of 66 μm is attached to the first metal layer of the test laminate of each sample. The thickness of a substrate of the polyimide tape is 25 μm. The interface between the fluororesin layer and the adhesion layer is provided as a peeling start point. The polyimide tape, the first metal layer, and the adhesion layer were peeled off by pulling them at 50 mm/min such that the peeling direction was 1800 with respect to the bonding surface, and the strength at this time was measured. The results are shown in the “Peel strength” row in Tables 1 and 2.

### <Measurement of Length of Scooped Part>

For the laminate of each sample, a through-hole was formed from the second metal layer, and the length of a scooped part of the fluororesin layer near the interface between the fluororesin layer and the adhesion layer was measured. The method for forming the through-hole is as follows.

A dry film is attached to the second metal layer and exposed, and the second metal layer is etched. The dry film is then stripped to form an opening of 9125 μm in the second metal layer.

The opening is irradiated with CO₂ laser to form a through-hole. The output of the CO₂ laser is 18.5 W. This removes the fluororesin layer and the adhesion layer to expose the first metal layer in a size of φ110 μm. The through-hole is a blind via-hole.

The laminate was cut such that a cross section including the central axis of the blind via-hole was exposed, and in the cross section, the length of a scooped part of the fluororesin layer near the interface between the fluororesin layer and the adhesion layer was measured. The method for measuring the length of a scooped part has been described in Embodiment 1. The results are shown in the “Length of scooped part” row in Tables 1 and 2. In the “Evaluation” row of the length of a scooped part, an evaluation of A is given when the length of the scooped part is less than 15 μm, an evaluation of B is given when the length of the scooped part is 15 μm or more and less than 25 μm, and an evaluation of C is given when the length of the scooped part is 25 μm or more. When the evaluation of A or B is given, it is determined that the generation of a scooped part was suppressed. When the evaluation of C is given, it is determined that the generation of a scooped part was not suppressed.

### <Consideration>

Samples 3 to 5, Samples 7 to 10, and Samples 12, 14, and 15 correspond to Examples. These samples are circuit boards in which a fluororesin layer and an adherend layer are bonded together with an adhesion layer by pressing at a low temperature. It was confirmed that, in these samples, even in the case where a through-hole extending through the fluororesin layer and the adhesion layer was formed, the generation of a scooped part near the interface between the fluororesin layer and the adhesion layer was suppressed.

Samples 1, 2, 6, 11, and 13 correspond to Comparative Examples. It was confirmed that, in these samples, in the case where a through-hole extending through the fluororesin layer and the adhesion layer was formed, the generation of a scooped part was not suppressed.

In Sample 16, the fluororesin layer and the adherend layer could not be bonded together by pressing at a low temperature. This is probably because the content of fluororesins (PTFE and PFA) in the resin of the adhesion layer is 100% by mass, and the adhesion layer 12 is not softened in the pressing process. In Sample 16, since a test laminate was not obtained, laser processing of a laminate could not be performed. Thus, the length of a scooped part of Sample 16 could not be measured.

Appropriate combinations and various modifications of configurations of the embodiments and Examples described above are originally intended.

It is to be understood that the embodiments and Examples disclosed herein are only illustrative and non-restrictive in all respects. The scope of the present invention is defined not by the embodiments and Examples described above but by the appended claims and is intended to include all modifications that fall within the scope of the claims and the equivalents thereof.

### REFERENCE SIGNS LIST

1 circuit board
10 fluororesin layer
10a first main surface
10b second main surface
11 second metal layer
12 adhesion layer
12a first-B surface
13 first metal layer
13a first-A surface
14 connecting portion
15 third metal layer
16 first resin layer
16a third main surface
16b fourth main surface
17 adherend layer
20 fluororesin laminate
22 first resin laminate
24 first laminate
25 scooped part
26 filling portion
27 inner wall surface
L1 central axis
P1 interface

1. A circuit board comprising:
a fluororesin layer;
an adherend layer; and
an adhesion layer bonding the fluororesin layer and the adherend layer together,
wherein the fluororesin layer contains polytetrafluoroethylene and a first inorganic filler,
a content of the first inorganic filler in the fluororesin layer is 50% by volume to 66% by volume,
the adhesion layer contains a resin and a second inorganic filler,
a content of a fluororesin in the resin is 5% by mass or less,
a content of the second inorganic filler in the adhesion layer is 29% by volume to 47% by volume, and
a through-hole extending through the fluororesin layer and the adhesion layer is formed.

2. The circuit board according to claim 1, wherein the first inorganic filler contains silica.

3. The circuit board according to claim 1, wherein the second inorganic filler contains silica.

4. The circuit board according to claim 1, wherein the second inorganic filler contains boron nitride.

5. The circuit board according to claim 1,
wherein at least one of an inner wall surface of the fluororesin layer defining a part of the through-hole and an inner wall surface of the adhesion layer defining a part of the through-hole has a scooped part, and
the scooped part has a length of less than 25 μm.

6. The circuit board according to claim 1, wherein the adhesion layer has a ratio A/B of an elastic modulus A at 160° C. to an elastic modulus B at 20° C. of 0.08 or less.

7. The circuit board according to claim 1, wherein the resin contains a polyolefin or a polystyrene-based elastomer.

8. The circuit board according to claim 1,
wherein the adherend layer includes a first metal layer and a first resin layer, and
the first metal layer is disposed on a surface of the first resin layer facing the fluororesin layer.

9. The circuit board according to claim 1;
wherein the adherend layer includes a first metal layer and a first resin layer, and
the first resin layer is disposed on a surface of the first metal layer facing the fluororesin layer.

10. The circuit board according to claim 8,
wherein the fluororesin layer has a first main surface facing the adhesion layer and a second main surface opposite to the first main surface, and
the circuit board further comprises a second metal layer disposed on the second main surface.

11. The circuit board according to claim 10, further comprising a connecting portion electrically connecting the first metal layer and the second metal layer to each other,
wherein the connecting portion is formed in the through-hole.

12. The circuit board according to claim 10, wherein, when viewed from a direction perpendicular to the second main surface, the first metal layer is formed in a region overlapping the through-hole.

13. The circuit board according to claim 10, wherein, when viewed from a direction perpendicular to the first main surface, the second metal layer is formed in a region overlapping the through-hole.

14. A method of manufacturing the circuit board according to claim 1, the method comprising:
holding a laminate in which the fluororesin layer, the adhesion layer, and the adherend layer are stacked in this order at a temperature of 180° C. or lower to soften the adhesion layer, thereby bonding the fluororesin layer and the adherend layer together.

15. A method of manufacturing a circuit board, the method comprising:
preparing a fluororesin laminate including a fluororesin layer having a first main surface and a second main surface opposite to the first main surface, and a second metal layer disposed on the second main surface;
preparing a first resin laminate including a first resin layer having a third main surface and a fourth main surface opposite to the third main surface, and a first metal layer disposed on the third main surface;
preparing an adhesion layer;
forming a first laminate by stacking the fluororesin laminate, the adhesion layer, and the first resin laminate in this order such that the first main surface is in contact with the adhesion layer and holding the adhesion layer at a temperature of 180° C. or lower to soften the adhesion layer, thereby bonding the fluororesin laminate and the first resin laminate together;
removing at least a part of the fluororesin layer and at least a part of the adhesion layer to form a through-hole extending through the fluororesin layer and the adhesion layer; and
forming a connecting portion on an inner wall surface of the fluororesin layer defining a part of the through-hole and an inner wall surface of the adhesion layer defining a part of the through-hole,
wherein the fluororesin layer contains polytetrafluoroethylene and a first inorganic filler,
a content of the first inorganic filler in the fluororesin layer is 50% by volume to 66% by volume,
the adhesion layer contains a resin and a second inorganic filler,
a content of a fluororesin in the resin is 5% by mass or less, and
a content of the second inorganic filler in the adhesion layer is 29% by volume to 47% by volume.

16. The method of manufacturing a circuit board according to claim 15, wherein the preparing the first resin laminate further includes forming a first circuit on the first resin laminate by etching at least a part of the first metal layer.

17. The method of manufacturing a circuit board according to claim 15, wherein the preparing the fluororesin laminate further includes forming a second circuit on the fluororesin laminate by etching at least a part of the second metal layer.

18. The method of manufacturing a circuit board according to claim 15, wherein the forming the first laminate further includes forming a second circuit on the fluororesin laminate by etching at least a part of the second metal layer.

19. The method of manufacturing a circuit board according to claim 15, wherein the through-hole is formed by laser processing.

20. The method of manufacturing a circuit board according to claim 15,
wherein at least one of the inner wall surface of the fluororesin layer and the inner wall surface of the adhesion layer has a scooped part, and
the scooped part has a length of less than 25 μm.
